(19) United States
(12) Patent Application Publication
(10) Pub. No.: US 2023/0180569 A1
(43) Pub. Date: Jun. 8, 2023

(54) DISPLAY DEVICE

(71) Applicant: Samsung Display Co., LTD., Yongin-si (KR)

(72) Inventors: Chan Jae PARK, Suwon-si (KR); Sun Hee OH, Seoul (KR)

(21) Appl. No.: 18/071,443

(22) Filed: Nov. 29, 2022

(30) Foreign Application Priority Data
Dec. 2, 2021 (KR) 10-2021-0170953

(51) Int. Cl. H10K 59/35; H10K 50/86; H10K 50/858; H10K 50/84; H10K 59/40

(52) U.S. Cl. CPC H01L 27/3218; H01L 51/5284; H01L 51/5275; H01L 51/5237; H01L 27/323; H01L 27/3216

(57) ABSTRACT

A display device includes: a display area; and a non-display area on at least one side of the display area, wherein the display area comprises: a plurality of rigid areas, in each of which at least one unit pixel comprising a plurality of sub-pixels is defined by a partition wall; and a stretchable area in which elastic connection members are formed between the plurality of rigid areas to enable a distance between the plurality of rigid areas to be increased or decreased.

### CROSS-REFERENCE TO RELATED APPLICATION

The present application claims priority to and the benefit of Korean Patent Application No. 10-2021-0170953 filed on Dec. 2, 2021 in the Korean Intellectual Property Office, the entire content of which is incorporated herein by reference.

### BACKGROUND

### 1. Field

Aspects of some embodiments of the present disclosure relate to a display device.

### 2. Description of the Related Art

As the information-oriented society evolves, various demands for display devices are ever increasing. For example, display devices may be utilized by a variety of electronic devices such as smart phones, digital cameras, laptop computers, navigation devices, and smart televisions.

Display devices may be flat panel display devices such as liquid-crystal display devices, field emission display devices, and light-emitting display devices. Light-emitting display devices include an organic light-emitting display device including an organic light-emitting element, an inorganic light-emitting display device including an inorganic light-emitting element such as an inorganic semiconductor, and a micro-LED display device including ultra-small light-emitting elements. In some instances, it may be desirable for a light-emitting display device to be stretchable in up and down and/or left to right directions.

The above information disclosed in this Background section is only for enhancement of understanding of the background and therefore the information discussed in this Background section does not necessarily constitute prior art.

### SUMMARY

Aspects of some embodiments of the present disclosure include a display device that may prevent or reduce deterioration of the quality of images displayed on a flexible display panel that is stretched and contracted.

It should be noted that characteristics of embodiments according to the present disclosure are not limited to the above-mentioned object; and other objects of the present disclosure will be apparent to those skilled in the art from the following descriptions.

According to some embodiments of the disclosure, a display device comprising a display area; and a non-display area located on at least one side of the display area, wherein the display area comprises a plurality of rigid areas, in each of which at least one unit pixel comprising a plurality of sub-pixels is defined by a partition wall, and a stretchable area in which elastic connection members are formed between the plurality of rigid areas so that a distance between the plurality of rigid areas is increased or decreased.

According to some embodiments, the at least one unit pixel located in each of the rigid areas comprises first to third sub-pixels or first to fourth sub-pixels, and wherein the first to third sub-pixels or the first to fourth sub-pixels are arranged in vertical or horizontal stripes or a Pentile™ matrix.

According to some embodiments, the at least one unit pixel located in each of the rigid areas comprises a reflection adjustment layer formed on its front surface to cover a black matrix, and wherein the reflection adjustment layer comprises an organic layer in which a dye is dispersed and an organic layer in which a pigment is dispersed, to absorb light in a predetermined wavelength range and transmit light in other wavelength ranges.

According to some embodiments, the elastic connection members comprise stretchable lines connected between the plurality of rigid areas to transmit an electrical signal to the at least one unit pixel; first elastic members attached between rear surfaces of the stretchable lines and the rigid areas, stretched by an external force and contracted by an elastic force; and second elastic members attached between front surfaces of the stretchable lines and the rigid areas, stretched by an external force and contracted by an elastic force.

According to some embodiments, each of the rigid areas comprises an optical adjustment layer formed on a front surface of the reflection adjustment layer defined by the partition wall to refract and scatter light after the light has transmitted the reflection adjustment layer.

According to some embodiments, each of the rigid areas further comprises an anti-moisture member formed to completely cover an outer surface thereof, comprising the partition wall and the optical adjustment layer, and wherein the second elastic members cover all of the stretchable lines and are attached to the anti-moisture member of the rigid areas.

According to some embodiments, each of the rigid areas further comprises an adhesive member formed to completely cover an outer surface thereof, comprising the partition wall and the optical adjustment layer, and wherein the elastic members cover all of the stretchable lines and are attached to the adhesive member of the rigid areas.

According to some embodiments, the rigid areas further comprise refraction patterns formed on a front surface of the reflection adjustment layer defined by the partition wall to refract and scatter light after the light has transmitted the reflection adjustment layer, and wherein the refraction patterns are formed in a shape of a convex lens so that a refractive index thereof is different from a refractive index of the reflection adjustment layer.

According to some embodiments, the second elastic members are formed of a transparent synthetic material based on elastomers, to cover all of the refraction patterns and the stretchable lines while being attached to side surfaces of adjacent ones of the rigid areas.

According to some embodiments, the rigid areas further comprise a flat window plate formed on a front surface comprising the partition wall and the reflection adjustment layer, and wherein the window plate comprises a flat portion located on a front portion of the rigid areas, and a deformable portion located on a front portion of the stretchable area.

According to some embodiments, the second elastic members are formed of a transparent synthetic material based on elastomers, to cover all of the window plate and the stretchable lines while being attached to side surfaces of adjacent ones of the rigid areas.

According to some embodiments of the disclosure, a display device comprising a display area; and a non-display area located on at least one side of the display area, wherein the display area comprises a plurality of rigid areas, in each of which a respective one of sub-pixels is defined by a partition wall, and a stretchable area in which elastic connection members are formed between the plurality of rigid areas so that a distance between the plurality of rigid areas is decreased or increased.

According to some embodiments, each of the sub-pixels located in the respective rigid areas comprises a reflection adjustment layer formed on a front surface to cover a black matrix, and wherein the reflection adjustment layer comprises an organic layer in which a dye is dispersed and an organic layer in which a pigment is dispersed, to absorb light in a predetermined wavelength range and transmit light in other wavelength ranges.

According to some embodiments, the elastic connection members comprise stretchable lines connected between the rigid areas to transmit an electrical signal between the sub-pixels, first elastic members physically attached between rear surfaces of the stretchable lines and the rigid areas, stretched by an external force and contracted by an elastic force, and second elastic members physically attached between front surfaces of the stretchable lines and the rigid areas, stretched by an external force and contracted by an elastic force.

According to some embodiments, each of the rigid areas further comprises an optical adjustment layer formed on a front surface of the reflection adjustment layer defined by the partition wall to refract and scatter light after the light has transmitted the reflection adjustment layer.

According to some embodiments, each of the rigid areas further comprises an anti-moisture member formed to completely cover an outer surface thereof, comprising the partition wall and the optical adjustment layer, and wherein the elastic members cover all of the stretchable lines and are attached to the anti-moisture member of the sub-pixels.

According to some embodiments, each of the rigid areas further comprises an adhesive member formed to completely cover an outer surface thereof, comprising the partition wall and the optical adjustment layer, and wherein the elastic members cover all of the stretchable lines and are attached to the adhesive member of the rigid areas.

According to some embodiments, the rigid areas further comprise refraction patterns formed on a front surface of the reflection adjustment layer defined by the partition wall to refract and scatter light after the light has transmitted the reflection adjustment layer, and wherein the refraction patterns are formed in a shape of a convex lens so that a refractive index thereof is greater than a refractive index of the reflection adjustment layer.

According to some embodiments, the second elastic members are formed of a transparent synthetic material based on elastomers, to cover all of the refraction patterns and the stretchable lines while being attached to side surfaces of adjacent ones of the rigid areas.

According to some embodiments, each of the rigid areas further comprises a flat window plate formed on a front surface of the partition wall and the reflection adjustment layer, and wherein a refractive index of the window plate is different from that of the reflection adjustment layer.

According to some embodiments of the present disclosure, the quality of images displayed on a display device may be maintained without deterioration even when a display panel for displaying the images is stretched or contracted, so that user satisfaction can be improved.

It should be noted that characteristics of embodiments according to the present disclosure are not limited to those described above and other characteristics of embodiments according to the present disclosure will be apparent to those skilled in the art from the following descriptions.

### BRIEF DESCRIPTION OF THE DRAWINGS

The above and other aspects and features of the present disclosure will become more apparent by describing in more detail aspects of some embodiments thereof with reference to the attached drawings, in which:

FIG. 1 is a plan view showing a display device according to some embodiments of the present disclosure.

FIG. 2 is a side view showing a display device according to some embodiments of the present disclosure.

FIG. 3 is a circuit diagram showing a sub-pixel in a display area according to some embodiments of the present disclosure.

FIG. 4 is a layout view showing a display area when it is contracted as a display panel is contracted according to some embodiments.

FIG. 5 is a layout view showing a display area and rigid areas of a display panel when they are stretched according to some embodiments.

FIG. 6 is a layout view showing a display area when it is contracted as a display panel is contracted according to some embodiments.

FIG. 7 is a layout view showing a display area when it is contracted as a display panel is contracted according to some embodiments.

FIG. 8 is a layout view showing a display area when it is stretched as the display panel is stretched according to some embodiments.

FIG. 9 is yet another layout view showing a display area when it is contracted as a display panel is contracted according to some embodiments.

FIG. 10 is a cross-sectional view showing an example of a display panel taken along the line I-I′ of FIG. 5 according to some embodiments.

FIG. 11 is a cross-sectional view schematically showing the configuration of the cross section taken along the line I-I of FIG. 5 in the form of blocks according to some embodiments.

FIG. 12 is a cross-sectional view showing another example of the black matrix and the partition wall shown in FIG. 10 according to some embodiments.

FIG. 13 is a cross-sectional view showing yet another example of the black matrix and the partition wall shown in FIG. 10 according to some embodiments.

FIG. 14 is a cross-sectional view showing another example of the black matrix and the reflection adjustment layer shown in FIG. 10 according to some embodiments.

FIG. 15 is a cross-sectional view schematically showing an example of the display panel taken along the line Z-Z′ of FIG. 5 in the form of blocks according to some embodiments.

FIG. 16 is a cross-sectional view illustrating a method of fabricating the display panel shown in FIGS. 10 and 11 according to some embodiments.

FIG. 17 is a cross-sectional view additionally illustrating a method of fabricating the display panel shown in FIGS. 10 and 11 according to some embodiments.

FIG. 18 is a cross-sectional view schematically showing another example of the configuration of the display panel, taken along the line Z-Z′ of FIG. 5 according to some embodiments.

FIG. 19 is a cross-sectional view schematically showing yet another example of the configuration of the display panel, taken along the line Z-Z′ of FIG. 5.

FIG. 20 is another cross-sectional view schematically showing the configuration of the display panel according to some embodiments, taken along the line Z-Z′ of FIG. 5.

FIG. 21 is yet another cross-sectional view schematically showing the configuration of the display panel according to some embodiments, taken along the line Z-Z′ of FIG. 5.

FIG. 22 is a cross-sectional view illustrating a method of fabricating the display panel shown in FIG. 21 according to some embodiments.

FIG. 23 is a cross-sectional view schematically showing a configuration of the display panel shown in FIG. 21 according to some embodiments.

FIG. 24 is a cross-sectional view schematically showing another example of the configuration of the display panel, taken along the line Z-Z′ of FIG. 5 according to some embodiments.

FIG. 25 is yet another cross-sectional view schematically showing another example of the configuration of the display panel, taken along the line Z-Z′ of FIG. 5 according to some embodiments.

FIG. 26 is a cross-sectional view showing a method of fabricating the display panel shown in FIG. 15 according to some embodiments.

FIG. 27 is a layout view showing a display area when it is contracted as a display panel is contracted according to some embodiments.

FIG. 28 is a layout view showing a display area when it is stretched as the display panel is stretched according to some embodiments.

FIG. 29 is a cross-sectional view schematically showing an example of the display panel taken along the line H-H′ of FIG. 28 in the form of blocks.

FIG. 30 is a cross-sectional view schematically showing another example of the configuration of the display panel, taken along the line H-H′ of FIG. 28 according to some embodiments.

FIG. 31 is a cross-sectional view schematically showing yet another example of the configuration of the display panel, taken along the line H-H′ of FIG. 28 according to some embodiments.

FIG. 32 is another cross-sectional view schematically showing an example of the configuration of the display panel, taken along the line H-H′ of FIG. 28 according to some embodiments.

FIG. 33 is a cross-sectional view schematically showing yet another example of the configuration of the display panel, taken along the line H-H′ of FIG. 28 according to some embodiments.

FIG. 34 is a view showing an example of a wearable device including a display device according to some embodiments of the present disclosure.

FIG. 35 is a view showing an example of a foldable smart device including a display device according to some embodiments of the present disclosure.

FIG. 36 is a view showing an example of a large monitor including a display device according to some embodiments.

### DETAILED DESCRIPTION

Aspects of some embodiments of the present invention will now be described more fully hereinafter with reference to the accompanying drawings, in which some embodiments of the invention are shown. The present invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, aspects of some embodiments of the present disclosure will be described in more detail reference to the accompanying drawings.

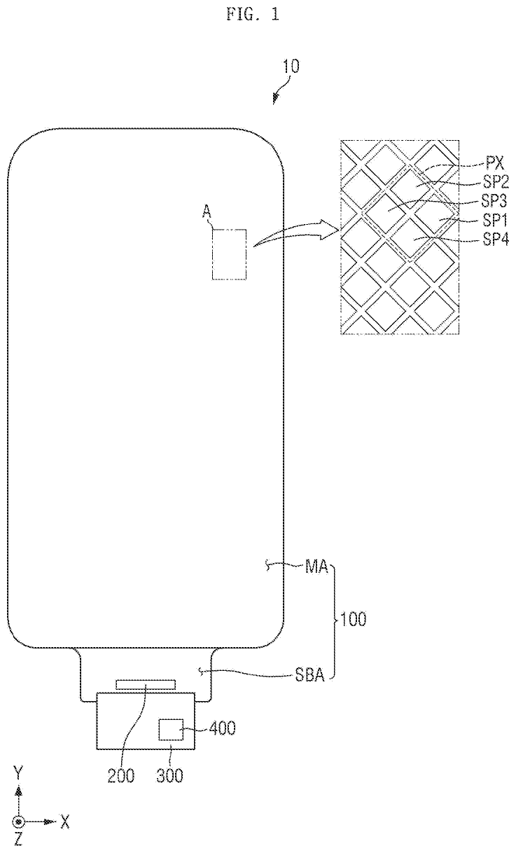

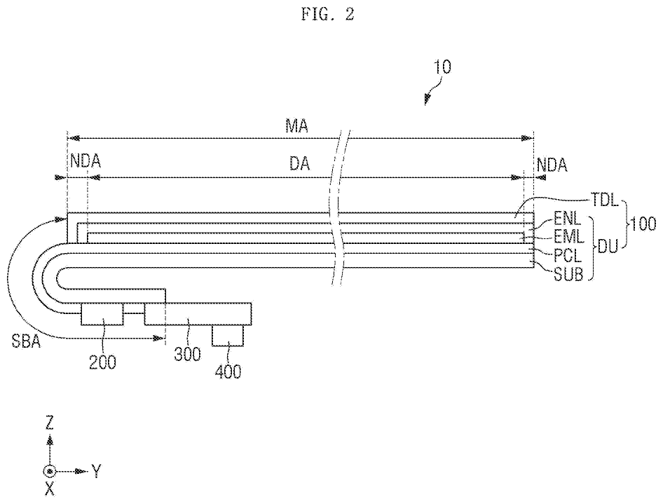

FIG. 1 is a plan view showing a display device according to some embodiments of the present disclosure. FIG. 2 is a view showing a side of a display device according to some embodiments of the present disclosure.

Referring to FIGS. 1 to 2, a display device 10 is configured to display moving (e.g., video) images or still (e.g., static) images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard, and an Internet of Things (IoT) device.

The display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, and an ultra-small light-emitting display device using micro or nano light-emitting diodes (micro LEDs or nano LEDs). In the following description, an organic light-emitting display device is described as an example of the display device 10. It is, however, to be understood that the present disclosure is not limited thereto.

According to some embodiments of the present disclosure, the display device 10 includes a display panel 100, a display driver circuit 200, a display circuit board 300 and a touch driver circuit 400.

The display panel 100 may be formed in a rectangular plane having shorter sides in a first direction (x-axis direction) and longer sides in a second direction (y-axis direction) intersecting the first direction (x-axis direction). Each of the corners where the shorter sides in the first direction (x-axis direction) meet the longer sides in the second direction (y-axis direction) may be rounded with a predetermined curvature or may be a right angle. The shape of the display panel 100 when viewed from the top (e.g., in a plan view) is not limited to a quadrangular shape, but may be formed in a different polygonal shape, a circular shape, or an elliptical shape. The display panel 100 may be formed to be flat or planar, but embodiments according to the present disclosure are not limited thereto. For example, the display panel 100 includes curved portions formed at left and right ends and having a constant curvature or a varying curvature. In addition, the display panel 100 may be flexible so that it can be curved, bent, folded or rolled. For example, the display panel 100 according to some embodiments of the present disclosure may be flexible so that it can be stretched or contracted in the direction parallel to the shorter sides, i.e., the first direction (x-axis direction) and in the direction parallel to the longer sides, i.e., the second direction (y-axis direction) intersecting the first direction (x-axis direction).

The display panel 100 may include the main area MA and a subsidiary area SBA. For example, the main area MA includes a display area DA where images are displayed, and a non-display area NDA around the display area DA. For example, the non-display area NDA may be on at least one side of the display area DA. The display area DA includes unit pixels PX displaying an image. The subsidiary area SBA may protrude from one side of the main area MA in the second direction (y-axis direction). The subsidiary area SBA may be bent as shown in FIG. 2, and may be located on the rear side of the display panel 100 when it is bent. When the subsidiary area SBA is bent, it may overlap with the main area MA in the third direction (z-axis direction), which is the thickness direction of the substrate SUB.

In the display area DA of the display panel 100, unit pixels PX are arranged, each of which includes a plurality of sub-pixels SP1, SP2, SP3 and SP4 to display images using the plurality of sub-pixels SP1, SP2, SP3 and SP4. The sub-pixels SP1, SP2 SP3 and SP4 of each of the unit pixels PX may be arranged in a Pentile™ matrix, or may be arranged in vertical or horizontal stripes. The arrangement structure of each of the sub-pixels SP1, SP2, SP3 and SP4 will be described in more detail later with reference to the accompanying drawings. The display area DA in which the plurality of unit pixels PX is arranged may occupy most of the main area MA. The layout and the arrangement structure of the sub-pixels SP1, SP2 SP3 and SP4 and the definition of the unit pixels PX will be described later in more detail with reference to the accompanying drawings.

The display driver circuit 200 may be located in the subsidiary area SBA. In addition, as shown in FIG. 2, the display panel 100 includes a substrate SUB, a pixel circuit layer PCL, an emission material layer EML, an encapsulation film TFEL, and a touch detecting layer TDL.

The pixel circuit layer PCL may be located on the substrate SUB. The pixel circuit layer PCL may be located in the main area MA and the subsidiary area SBA. The pixel circuit layer PCL includes thin-film transistors.

The emission material layer EML may be located on the pixel circuit layer PCL. The emission material layer EML may be located in the display area DA of the main area MA. The emission material layer EML includes light-emitting elements located in emission areas.

The encapsulation layer ENL may be located on the emission material layer EML. The encapsulation layer ENL may be located in the display area DA and the non-display area NDA of the main area MA. The encapsulation layer ENL includes at least one inorganic layer and at least one organic layer for encapsulating the emission material layer.

The touch detecting layer TDL may be formed or located on the encapsulation layer ENL. The touch detecting layer TDL may be formed or located on the front surface of the main area MA, i.e., in the display area DA and the non-display area NDA. The touch detecting layer TDL may sense a touch of a person or an object using sensor electrodes.

A cover window for protecting the display panel 100 from above may be located on the touch detecting layer TDL. The cover window may be attached on the touch detecting layer TDL by a transparent adhesive member such as an optically clear adhesive (OCA) film and an optically clear resin (OCR). The cover window may be an inorganic material such as glass, or an organic material such as plastic and polymer material. In order to prevent or reduce deterioration of image visibility due to reflection of external light, a polarizing film may be further located between the touch detecting layer TDL and the cover window.

The display driver circuit 200 may generate signals and voltages for driving the display panel 100. The display driving circuit 200 may be implemented as an integrated circuit (IC) and may be attached to the display panel 10 by a chip on glass (COG) technique, a chip on plastic (COP) technique, or an ultrasonic bonding. It is, however, to be understood that embodiments according to the present disclosure are not limited thereto. For example, the display driver circuit 200 may be attached on the display circuit board 300 by the chip-on-film (COF) technique.

The display circuit board 300 may be attached to one end of the subsidiary area SBA of the display panel 100. Accordingly, the display circuit board 300 may be electrically connected to the display panel 100 and the display driver circuit 200. The display panel 100 and the display driver circuit 200 may receive digital video data, timing signals, and driving voltages through the display circuit board 300. The display circuit board 300 may be a flexible printed circuit board, a printed circuit board, or a flexible film such as a chip-on film.

The touch driving circuit 400 may be located on the display circuit board 300. The touch driver circuit 400 may be implemented as an integrated circuit (IC) and may be attached on the display circuit board 300.

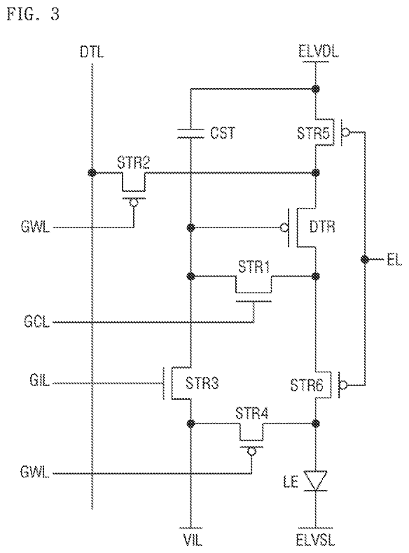

FIG. 3 is a circuit diagram showing a sub-pixel in a display area according to some embodiments of the present disclosure.

For example, FIG. 3 is a circuit diagram showing one sub-pixel among the plurality of sub-pixels SP1, SP2, SP3 and SP4 included in each of the unit pixels PX. The sub-pixels SP1, SP2, SP3 and SP4 may have the same circuit structure except the connection relationship of the lines and the sizes.

Each of the sub-pixels includes a driving transistor DTR, switch elements, and a capacitor CST. The switch elements may include first to sixth switching transistors STR1, STR2, STR3, STR4, STRS and STR6.

The driving transistor DTR includes a gate electrode, a first electrode, and a second electrode. A drain-source current Ids (hereinafter referred to as “driving current”) of driving transistor DTR flowing between the first electrode and the second electrode is controlled according to the data voltage applied to the gate electrode.

The capacitor CST is formed between the gate electrode of the driving transistor DTR and the first supply voltage line ELVDL. One electrode of the capacitor CST may be connected to the gate electrode of the driving transistor DT while the other electrode thereof may be connected to the first supply voltage line ELVDL.

When the first electrode of each of the first to sixth switching transistors STR1, STR2, STR3, STR4, STR5 and STR6 and the driving transistor DTR is the source electrode, the second electrode thereof may be the drain electrode. Alternatively, when the first electrode of each of the first to sixth switching transistors STR1, STR2, STR3, STR4, STR5 and STR6 and the driving transistor DTR is the drain electrode, the second electrode thereof may be the source electrode.

For example, the active layer of each of the driving transistor DTR, the second switching transistor STR2, the fourth switching transistor STR4, the fifth switching transistor STR5 and the sixth switching transistor STR6 implemented as p-type metal oxide semiconductor field effect transistors (MOSFETs) may be made of polysilicon, and the active layer of each of the first switching transistor STR1 and the third switching transistor STR3 implemented as n-type MOSFETs may be made of oxide semiconductor.

Although the first to sixth switching transistors STR1, STR2, STR3, STR4, STR5 and STR6 and the driving transistor DTR are of n-type metal oxide semiconductor field effect transistors (MOSFETs), each active layer may be formed of one of polysilicon, amorphous silicon, and oxide semiconductor.

The gate electrode of the second switching transistor STR2 and the gate electrode of the fourth switching transistor STR4 may be connected to a first scan line GWL, and the gate electrode of the first switching transistor STR1 may be connected to a second scan line GCL. In addition, when the first switching transistor STR1 and the third switching transistor STR3 are formed of n-type MOSFETs, a scan signal of a gate-high voltage may be applied to the second scan line GCL and a third scan line GIL. In contrast, because the second switching transistor STR2, the fourth switching transistor STR4, the fifth switching transistor STR5 and the sixth switching transistor STR6 are formed of p-type MOSFETs, a scan signal of a gate-low voltage may be applied to the first scan line GWL and an emission line EL.

It should be noted that the equivalent circuit diagram of each of the pixels according to some embodiments of the present disclosure is not limited to that shown in FIG. 3. The equivalent circuit diagram of the pixel according to the embodiments of the present disclosure may be implemented as any other circuit structures known in the art than that of the embodiments shown in FIG. 3. For example, some embodiments may include additional components or fewer components without departing from the spirit and scope of embodiments according to the present disclosure.

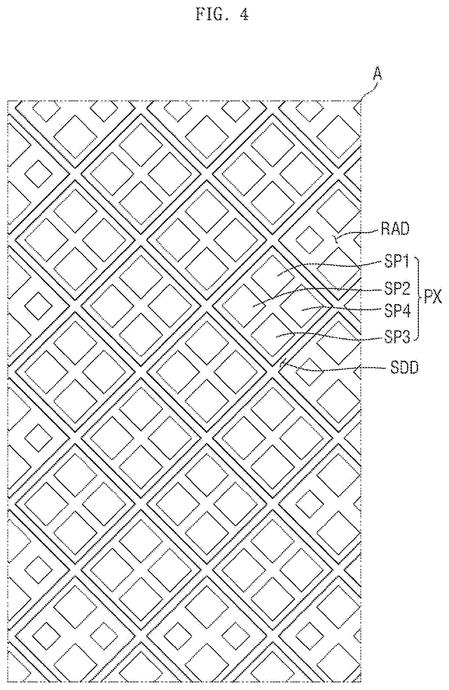

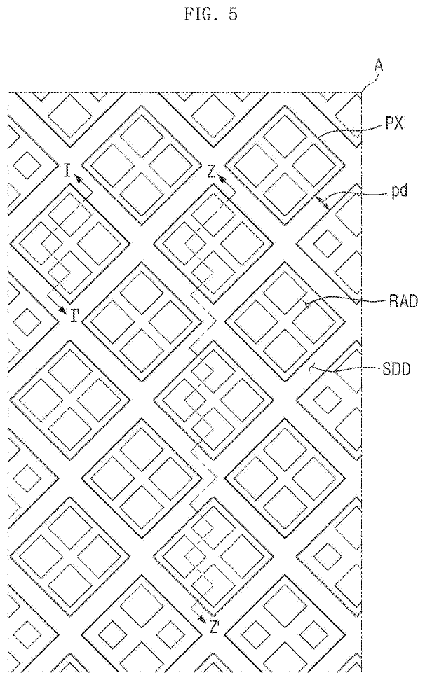

FIG. 4 is a layout view showing a display area when it is contracted as a display panel is contracted according to some embodiments. FIG. 5 is a layout view showing a display area and rigid areas of a display panel when they are stretched according to some embodiments.

For example, FIGS. 4 and 5 show the display area DA in area A shown in FIG. 1 when it is contracted or stretched as the display panel 100 is contracted or stretched.

In the display area DA, first to fourth sub-pixels SP1 to SP4 and a plurality of unit pixels PX each including the first to fourth sub-pixels SP1 to SP4 may be arranged in a Pentile™ matrix, to display images. The first to fourth sub-pixels SP1 , the second sub-pixel SP2, the third sub-pixel SP3, and the fourth sub-pixel SP4 included in each of the unit pixels PX may emit red light, green light, blue light and white light, respectively, to display images. In addition, the first to fourth sub-pixels SP1 to SP4 may emit lights of different colors such as red, green, blue and green or may emit light of the same color, to display images.

As shown in FIGS. 4 and 5, the display area DA of the display panel 100 includes a plurality of rigid areas RAD, and a stretchable area SDD located between the plurality of rigid areas RAD.

The rigid areas RAD include the unit pixels PX partitioned by the partition wall, respectively. Each of the unit pixels PX includes the first to fourth sub-pixels SP1 to SP4 arranged in a Pentile™ matrix. For example, in each of the rigid areas RAD, the first to fourth sub-pixels SP1 to SP4 forming one unit pixel PX may be arranged in the Pentile™ matrix, and thus the area where each unit pixel PX is located may be defined as the rigid area RAD.

The stretchable area SDD is located between the rigid areas RAD. Elastic connection members are included in the stretchable area SDD, so that the distance pd between the ridges areas RAD can be decreased or increased. Accordingly, the where in which the elastic connection members are formed may be defined as the stretchable area SDD, and the distance pd between the rigid areas RAD can be increased or decreased as the elastic connection members are stretched or contracted.

Each of the unit pixels PX located in the respective rigid area RAD is electrically connected with another adhesive unit pixel PX by a stretchable line included in the elastic connection members. Accordingly, the distances between the unit pixels PX may also be increased or decreased as the elastic connection members including the stretchable lines are stretched or contracted.

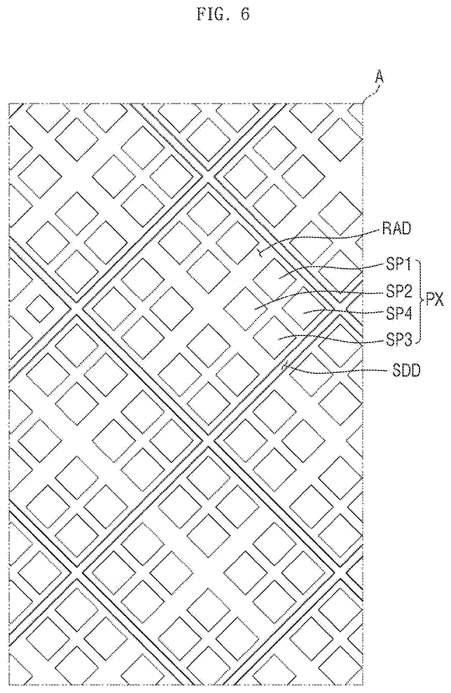

FIG. 6 is a layout view showing a display area when it is contracted as a display panel is contracted according to some embodiments.

As shown in FIG. 6, each of the rigid areas RAD may include a plurality of unit pixels PX partitioned by a partition wall. Accordingly, the area where a plurality of unit pixels PX partitioned by the partition wall is located may be defined as a rigid area RAD. For example, each of the rigid areas RAD may include a plurality of unit pixels PX arranged in a Pentile™ matrix, for example, a plurality of unit pixels PX arranged in a 2×2 matrix.

Likewise, the area between the rigid areas RAD is defined as a stretchable area SDD. The elastic connection members are formed in the stretchable area SDD so that the distance pd between the rigid areas RAD can be increased or decreased.

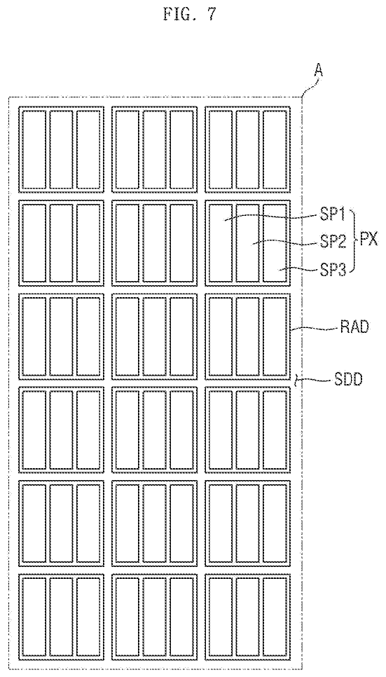

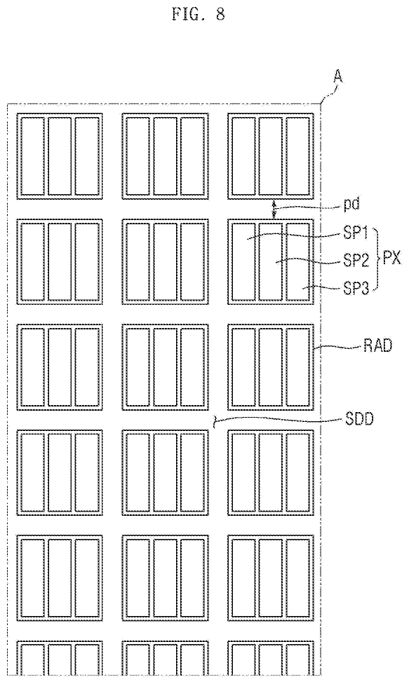

FIG. 7 is a layout view showing a display area when it is contracted as a display panel is contracted according to some embodiments. FIG. 8 is a layout view showing a display area when it is stretched as the display panel is stretched according to some embodiments.

As another example, referring to FIGS. 7 and 8, each of the rigid areas RAD includes the unit pixels PX partitioned by the partition wall. Each of the unit pixels PX may include a first sub-pixel SP1, a second sub-pixel SP2, and a third sub-pixel SP3 arranged in vertical or horizontal stripes. For example, in each of the rigid areas RAD, the first to third sub-pixels SP1 to SP3 forming one unit pixel PX may be arranged in horizontal stripes, and thus the area where each unit pixel PX including the first to third sub-pixel SP1 to SP3 is located may be defined as the rigid area RAD.

The stretchable area SDD is located between the rigid areas RAD. Similarly, elastic connection members are included in the stretchable area SDD, so that the distance pd between the ridges areas RAD can be increased or decreased.

Each of the unit pixels PX arranged in vertical or horizontal stripes is also electrically connected to other adjacent unit pixels PX by elastic connection members of the stretchable area SDD. Accordingly, the distances between the unit pixels PX may also be increased or decreased as the elastic connection members including the stretchable lines are stretched or contracted.

As described above with reference to FIGS. 4 to 8, the plurality of unit pixels PX each including the first to third sub-pixels SP1 to SP3 or the first to fourth sub-pixels SP1 to SP4 may be arranged in vertical or horizontal stripes, or may be arranged in a Pentile™ matrix. In addition, an area in which at least one unit pixel PX is located may be defined as a rigid area RAD. In addition, the distances between the rigid areas RAD may be increased or decreased as the elastic connection members formed in the stretchable area SDD are stretched or contracted.

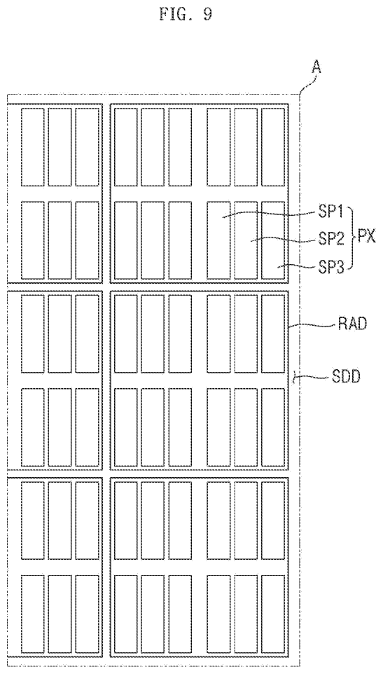

FIG. 9 is yet another layout view showing a display area when it is contracted as a display panel is contracted according to some embodiments.

As another example, referring to FIG. 9, each of the rigid areas RAD may include a plurality of unit pixels PX partitioned by the partition wall. Accordingly, the areas where the unit pixels PX partitioned by the partition wall are located may be defined as the rigid areas RAD. For example, each of the rigid areas RAD may include a plurality of unit pixels PX arranged in horizontal stripes, for example, a plurality of unit pixels PX arranged in a 2×2 matrix. Likewise, the area between the rigid areas RAD including the unit pixels PX is defined as a stretchable area SDD. The elastic connection members are formed in the stretchable area SDD so that the distance pd between the rigid areas RAD can be increased or decreased.

Hereinafter, a structure in which the unit pixels PX formed in the rigid areas RAD of FIG. 5 are electrically connected with one another by the elastic connection members of the stretchable area SDD will be described. It should be understood, however, that embodiments according to the present disclosure are not limited to the structure according to some embodiments.

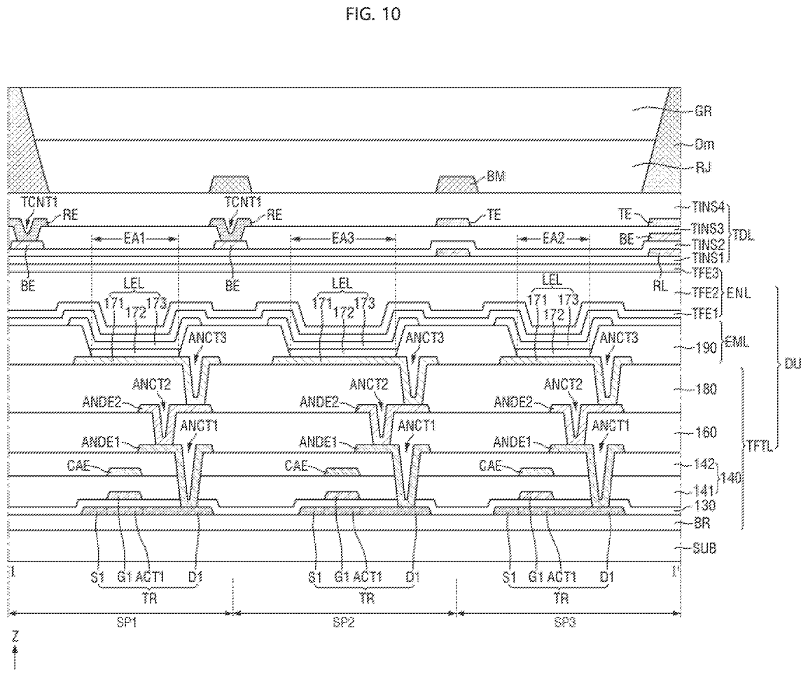

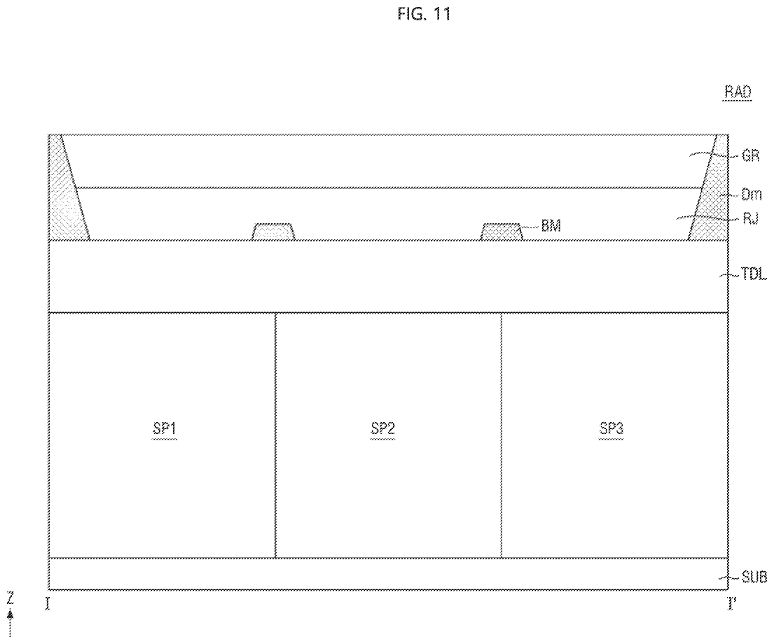

FIG. 10 is a cross-sectional view showing an example of a display panel taken along the line I-I′ of FIG. 10. FIG. 11 is a cross-sectional view schematically showing the configuration of the cross section taken along the line I-I of FIG. 10 in the form of blocks.

For example, FIG. 10 shows the cross-sectional structure of the first to third sub-pixels SP1, SP2 and SP3 in more detail. FIG. 11 schematically shows the cross-sectional structures of the first to third sub-pixels SP1, SP2 and SP3 shown in FIG. 10 in the form of blocks.

Referring to FIGS. 10 and 11, a barrier layer BR may be located on the substrate SUB of the rigid areas in which the first to third sub-pixels SP1, SP2 and SP3 are formed. The substrate SUB may be made of an insulating material such as a polymer resin. For example, the substrate SUB may be made of polyimide. The substrate SUB may be a flexible substrate that can be bent, folded, or rolled.

The barrier layer BR is a film for protecting the switching transistors of the pixel circuit layer PCL and an emissive layer 172 of the emission material layer EML from moisture permeating through the substrate SUB which is vulnerable to permeation of moisture. The barrier layer BR may be formed of multiple inorganic layers stacked on one another alternately. For example, the barrier layer BR may be made up of multiple layers in which one or more inorganic layers of a silicon nitride layer, a silicon oxynitride layer, a silicon oxide layer, a titanium oxide layer and an aluminum oxide layer are alternately stacked on one another.

Thin-film transistors TR may be located on the barrier layer BR. The thin-film transistors TR may be the driving transistor DTR or one of the first to sixth switching transistors STR1, STR2, STR3, STR4, STRS and STR6. In the following description, the driving transistor DTR will be described as an example. Each of the thin-film transistors TR includes an active layer ACT1, a gate electrode G1, a source electrode S1 and a drain electrode D1.

The active layer ACT1, the source electrode S1 and the drain electrode D1 of each of the thin-film transistors TR may be located on the barrier layer BR. The active layer ACT1 of each of the thin-film transistors TR includes polycrystalline silicon, single crystalline silicon, low-temperature polycrystalline silicon, amorphous silicon, or an oxide semiconductor. A part of the active layer ACT1 overlapping the gate electrode G1 in the third direction (z-axis direction) that is the thickness direction of the substrate SUB may be defined as a channel region. The source electrode S1 and the drain electrode D1 are regions that do not overlap with the gate electrode G1 in the third direction (z-axis direction), and may have conductivity by doping ions or impurities into a silicon semiconductor or an oxide semiconductor.

The thin-film transistors TR may be the driving transistor DTR and one of the first to sixth switching transistors STR1, STR2, STR3, STR4, STRS and STR6. A gate insulator 130 may be located on the active layer ACT1, the source electrode S1 and the drain electrode D1 of each of the thin-film transistors TR. The gate insulator 130 may be formed of an inorganic layer, for example, a silicon nitride layer, a silicon oxynitride layer, a silicon oxide layer, a titanium oxide layer, or an aluminum oxide layer.

The gate electrode G1 of each of the thin-film transistors TR may be located on the gate insulator 130. The gate electrode G1 may overlap the active layer ACT1 in the third direction (z-axis direction). The gate electrode G1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first interlayer dielectric layer 141 may be located on the gate electrode G1 of each of the thin-film transistors TR. The first interlayer dielectric layer 141 may be formed of an inorganic layer, for example, a silicon nitride layer, a silicon oxynitride layer, a silicon oxide layer, a titanium oxide layer, or an aluminum oxide layer. The first interlayer dielectric layer 141 may be made of a plurality of inorganic layers.

A capacitor electrode CAE may be located on the first interlayer dielectric layer 141. The capacitor electrode CAE may overlap the gate electrode G1 of the thin-film transistor TR in the third direction (z-axis direction). Because the first interlayer dielectric layer 141 has a predetermined dielectric constant, a capacitor can be formed by the capacitor electrode CAE, the gate electrode G1, and the first interlayer dielectric layer 141 located between them. The capacitor electrode CAE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second interlayer dielectric layer 142 may be arranged over the capacitor electrode CAE. The second interlayer dielectric layer 142 may be formed of an inorganic layer, for example, a silicon nitride layer, a silicon oxynitride layer, a silicon oxide layer, a titanium oxide layer, or an aluminum oxide layer. The second interlayer dielectric layer 142 may be made of a plurality of inorganic layers.

A first connection electrode ANDE1 may be located on the second interlayer dielectric layer 142. The first connection electrode ANDE1 may be connected to the drain electrode D1 of the thin-film transistor TR through a first connection contact hole ANCT1 that penetrates the gate insulator 130, the first interlayer dielectric layer 141 and the second interlayer dielectric layer 142. The first connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A first planarization layer 160 may be arranged over the first connection electrode ANDE1 for providing a flat surface over different heights due to the thin-film transistor TR. The first planarization layer 160 may be formed of an organic layer such as an acryl resin, an epoxy resin, a phenolic resin, a polyamide resin and a polyimide resin.

A second connection electrode ANDE2 may be located on the first planarization layer 160. The second anode connection electrode ANDE2 may be connected to the first anode connection electrode ANDE1 through a second connection contact hole ANCT2 penetrating the first planarization layer 160. The second connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second planarization layer 180 may be located on the second connection electrode ANDE2. The second planarization layer 180 may be formed as an organic layer such as an acryl resin, an epoxy resin, a phenolic resin, a polyamide resin and a polyimide resin.

Light-emitting elements LEL and a pixel-defining layer 190 may be located on the second planarization layer 180. Each of the light-emitting elements LEL includes a pixel electrode 171, an emissive layer 172, and a common electrode 173.

The pixel electrode 171 may be located on the second planarization layer 180. The pixel electrode 171 may be connected to the second connection electrode ANDE2 through a third connection contact hole ANCT3 penetrating the second planarization layer 180.

In the top-emission structure in which light exits from the emissive layer 172 toward the common electrode 173, the pixel electrode 171 may be made of a metal material having a high reflectivity such as a stack structure of silver (Ag) and indium tin oxide (ITO) (ITO/Ag/ITO), an APC alloy, and a stack structure of an APC alloy and ITO (ITO/APC/ITO). The APC alloy is an alloy of silver (Ag), palladium (Pd) and copper (Cu).

In order to define a first emission area EA1, a second emission area EA2, a third emission area EA3 and a fourth emission area EA4, the pixel-defining layer 190 may be formed to partition the pixel electrodes 171 on the second planarization layer 180. The pixel-defining layer 190 may be formed to cover the edges of the pixel electrode 171. The pixel-defining layer 190 may be formed of an organic layer such as an acryl resin, an epoxy resin, a phenolic resin, a polyamide resin and/or a polyimide resin.

In each of the first emission area EA1, the second emission area EA2 and the third emission area EA3, the pixel electrode 171, the emissive layer 172 and the common electrode 173 are stacked on one another sequentially, so that holes from the pixel electrode 171 and electrons from the common electrode 173 are recombined with each other in the emissive layer 172 to emit light.

The emissive layer 172 may be located on the pixel electrode 171 and the pixel-defining layer 190. The emissive layer 172 may include an organic material to emit light of a certain color. Functional layers such as a hole injection layer, a hole transporting layer, an organic material layer, an electron injection layer, an electron transporting layer, etc. may be located on the front and rear surfaces of the emissive layer 172.

The common electrode 173 may be located on the emissive layer 172. The common electrode 173 may be arranged to cover the emissive layer 172. The common electrode 173 may be a common layer formed commonly across the first emission area EA1, the second emission area EA2, and the third emission area EA3. A capping layer may be formed on the common electrode 173.

In the top-emission organic light-emitting diode, the common electrode 173 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is formed of a semi-transmissive metal material, the light extraction efficiency can be increased by using microcavities.

An encapsulation layer ENL may be located on the common electrode 173. (e.g., located on the capping layer described above) The encapsulation layer ENL includes at least one inorganic layer to prevent or reduce permeation of oxygen or moisture into the light-emitting element layer EML. In addition, the encapsulation layer ENL includes at least one organic layer to protect the light-emitting element layer EML from foreign substances such as dust. For example, the encapsulation layer ENL includes a first inorganic encapsulation layer TFE1, an organic encapsulation layer TFE2 and a second inorganic encapsulation layer TFE3.

The first inorganic encapsulation layer TFE1 may be located on the common electrode 173, the organic encapsulation layer TFE2 may be located on the first inorganic encapsulation layer TFE1, and the second inorganic encapsulation layer TFE3 may be located on the organic encapsulation layer TFE2. The first inorganic encapsulation layer TFE1 and the second inorganic encapsulation layer TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation layer TFE2 may be an organic layer such as an acryl resin, an epoxy resin, a phenolic resin, a polyamide resin, a polyimide resin, etc.

A touch detecting layer TDL may be located on the encapsulation layer ENL. The touch detecting layer TDL includes a first touch insulating layer TINS1, touch driving lines TL1 to TLn, touch sensing lines RL1 to RLn, a guard line GRL, a second touch insulating layer TINS2, connection electrodes BE, a third touch insulating layer TINS3, a driving electrode TE, a sensing electrode RE, and a fourth touch insulating layer TINS4.

The first touch insulating layer TINS1 may be formed of an inorganic layer, for example, a silicon nitride layer, a silicon oxynitride layer, a silicon oxide layer, a titanium oxide layer, or an aluminum oxide layer.

The touch driving lines TL1 to TLn, the touch sensing lines RL1 to RLn, and at least one guard line GRL may be located on the first touch insulating layer TINS1. The touch driving lines TL1 to TLn, the touch sensing lines RL1 to RLn and the at least one guard line GRL may be formed of one of: molybdenum (Mo), aluminum (Al), chromium (Cr), gold (Au), titanium (Ti), nickel (Ni), neodymium (Nd) and copper (Cu) or an alloy thereof.

The second touch insulating layer TINS2 is located on the first touch insulating layer TINS1 to cover all of the touch driving lines TL1 to TLn, the touch sensing lines RL1 to RLn, and the at least one guard line GRL. The second touch insulating layer TINS2 may be formed of an inorganic layer, for example, a silicon nitride layer, a silicon oxynitride layer, a silicon oxide layer, a titanium oxide layer, or an aluminum oxide layer, like the first touch insulating layer TINS1. The second touch insulating layer TINS2 may be thicker than the first touch insulating layer TINS1.

The connection electrodes BE may be located on the second touch insulating layer TINS2. The connection electrodes BE may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The third touch insulating layer TINS3 is arranged over the connection electrodes BE. The third touch insulating layer TINS3 may be formed of an organic layer such as an acryl resin, an epoxy resin, a phenolic resin, a polyamide resin and a polyimide resin. Alternatively, the third touch insulating layer TINS3 may be formed of an inorganic layer, i.e., a silicon nitride layer, a silicon oxynitride layer, a silicon oxide layer, a titanium oxide layer, or an aluminum oxide layer.

The driving electrodes TE, the sensing electrodes RE, and a dummy pattern DE may be located on the third touch insulating layer TINS3. The driving electrodes TE, the sensing electrodes RE, and a dummy pattern DE may be made of one of molybdenum (Mo), aluminum (Al), chromium (Cr), gold (Au), titanium (Ti), nickel (Ni), neodymium (Nd) and copper (Cu) or an alloy thereof. Although each of the driving electrodes TE, the sensing electrodes RE and the dummy pattern DE is made up of a single layer in the drawings, it may be made up of multiple layers.

The driving electrodes TE and the sensing electrodes RE may overlap with the connection electrodes BE in the third direction (z-axis direction). The sensing electrodes RE may be connected to the connection electrodes BE through touch contact holes TCNT1 penetrating through the third touch insulating layer TINS3.

The fourth touch insulating layer TINS4 is formed over the driving electrodes TE and the sensing electrodes RE. The fourth touch insulating layer TINS4 may provide a flat surface over level differences created by the driving electrodes TE, the sensing electrodes RE. To this end, the fourth touch insulating layer TINS4 may be formed of an inorganic layer, i.e., a silicon nitride layer, a silicon oxynitride layer, a silicon oxide layer, a titanium oxide layer, or an aluminum oxide layer. Alternatively, the fourth touch insulating layer TINS4 may be formed of an organic layer such as an acryl resin, an epoxy resin, a phenolic resin, a polyamide resin and/or a polyimide resin.

A black matrix BM and a partition wall Dm are formed on the touch detecting layer TDL, and the partition wall Dm partitions the unit pixels PX each including the first to fourth sub-pixels SP1 to SP4. The partition wall Dm may be formed of an inorganic layer such as a titanium oxide layer and an aluminum oxide layer, and may be formed of the same material as the black matrix BM. Such a partition wall Dm is larger and higher than the black matrix BM. The black matrix BM may have a shape of a mesh structure or a net structure, like the driving electrodes TE and the sensing electrodes RE. That is to say, the black matrix BM may not overlap the emission areas EA1, EA2 and EA3 of the sub-pixels SP1 to SP3.

A reflection adjustment layer RJ and an optical adjustment layer GR may be stacked on one another in each of the unit pixels PX partitioned by the partition wall Dm. The black matrix BM may have a shape of a mesh structure or a net structure, like the driving electrodes TE and the sensing electrodes RE. That is to say, the black matrix BM may not overlap the emission areas EA1, EA2, EA3 and EA4 of the sub-pixels SP1 to SP4.

The reflection adjustment layer RJ includes an organic layer in which a dye and pigment are dispersed at a predetermined ratio. The organic layer may absorb light of a particular wavelength range and transmit light in other wavelength ranges depending on the content and distribution of the dye and pigment. To this end, the content and distribution of the dye and pigment in the organic layer may be predetermined and applied depending on the light-emitting characteristics (e.g., luminance, reflectance, and reflected colors) of the sub-pixels SP1 to SP4. For example, the reflection adjustment layer RJ may selectively absorb light in wavelength ranges of approximately 490 nm to 605 nm, approximately 585 nm to 605 nm, or approximately 340 nm to 440 nm, depending on the content and distribution of dyes and pigments predetermined and applied in advance. As another example, the reflection adjustment layer RJ may selectively transmit light in wavelength ranges of approximately 620 nm to 750 nm, approximately 495 nm to 570 nm, or approximately 450 nm to 495 nm depending on the content and distribution of dyes and pigments predetermined and applied in advance. By virtue of the reflection adjustment layer RJ including such an organic layer in which the dye and the pigment are dispersed, optical control is possible without forming any additional color filter or polarizing layer.

The optical adjustment layer GR includes a light-transmitting organic material and is formed on the reflection adjustment layer RJ to refract and scatter light transmitting the reflection adjustment layer RJ. To this end, the optical adjustment layer GR may include a light-transmitting organic material such as an epoxy resin, an acrylic resin, a cardo resin and or an imide resin. In addition, the optical adjustment layer GR may further include scattering particles for scattering the light transmitting the reflection adjustment layer RJ in random directions. The scattering particles may include metal oxide particles or organic particles. For example, the metal oxide may be titanium oxide (TiO₂), zirconium oxide (ZrO₂), aluminum oxide (Al₂O₃), indium oxide (In₂O₃), zinc oxide (ZnO), or tin oxide (SnO₂). In addition, the organic particles may include an acrylic resin or a urethane-based resin. The diameter of the scattering particles may be several to several tens of nanometers.

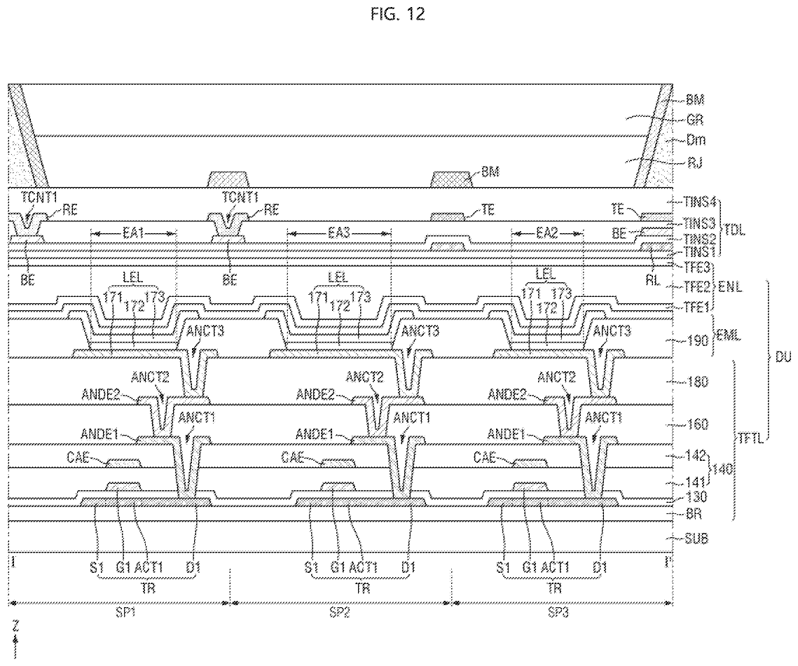

FIG. 12 is a cross-sectional view showing another example of the black matrix and the partition wall shown in FIG. 10.

Referring to FIG. 12, the partition wall Dm is formed on the touch detecting layer TDL to partition the unit pixels PX including the first to fourth sub-pixels SP1 to SP4. The partition wall Dm may be made up of an inorganic layer such as a titanium oxide layer and an aluminum oxide layer.

The black matrix BM may be formed on the touch detecting layer TDL including the partition wall Dm so that the first to fourth sub-pixels SP1 to SP4 are defined. Accordingly, the black matrix BM formed on the partition wall Dm may be formed to completely cover the partition wall Dm. The black matrix BM may have a shape of a mesh structure or a net structure, like the driving electrodes TE and the sensing electrodes RE. The black matrix BM may not overlap the emission areas EA1, EA2 and EA3 of the sub-pixels SP1 to SP3.

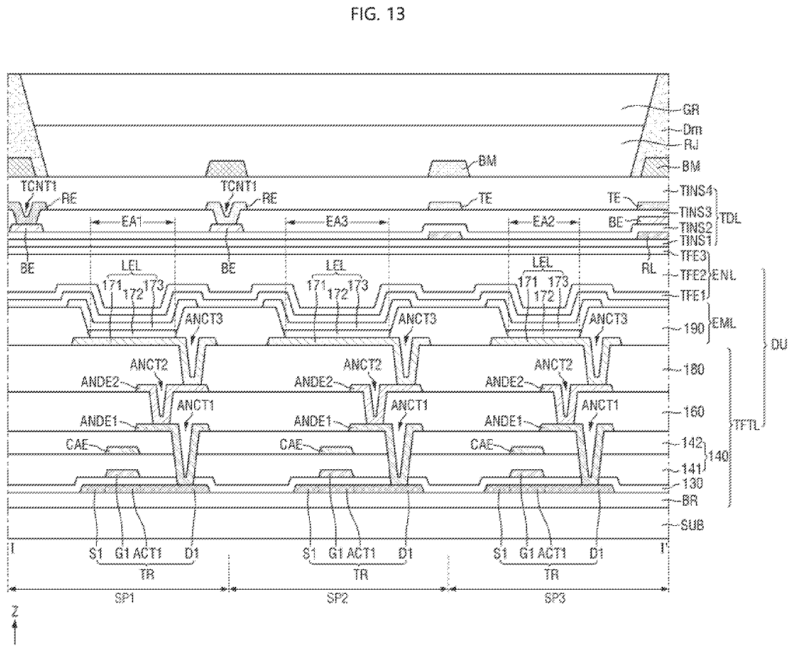

FIG. 13 is a cross-sectional view showing yet another example of the black matrix and the partition wall shown in FIG. 10.

Referring to FIG. 13, a black matrix BM may be formed on a touch detecting layer TDL so that the first to fourth sub-pixels SP1 to SP4 are defined. The black matrix BM may be formed of an inorganic layer such as a titanium oxide layer and an aluminum oxide layer. The black matrix BM may have a shape of a mesh structure or a net structure, like the driving electrodes TE and the sensing electrodes RE. Accordingly, as shown in FIG. 13, the black matrix BM may not overlap the emission areas EA1, EA2 and EA3 of the sub-pixels SP1 to SP3.

A partition wall Dm is formed on the touch detecting layer TDL including the black matrix BM to partition the unit pixels PX. The partition wall Dm may be formed to completely cover the black matrix BM formed in the borders where the unit pixels PX are partitioned. The partition wall Dm may be made up of an inorganic layer such as a titanium oxide layer and an aluminum oxide layer, which may be identical to or different from the black matrix BM.

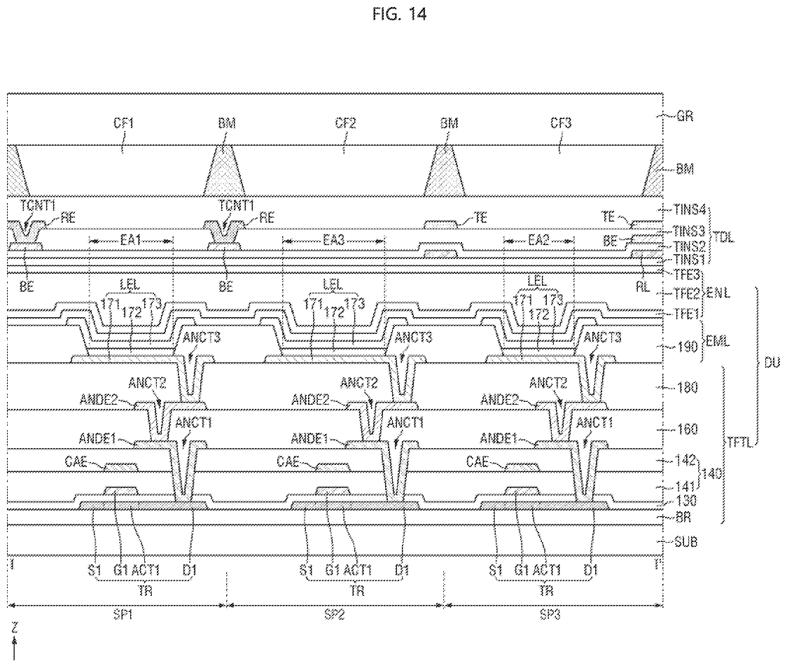

FIG. 14 is a cross-sectional view showing another example of the black matrix and the reflection adjustment layer shown in FIG. 10.

Referring to FIG. 14, a black matrix BM may be formed on a touch detecting layer TDL so that the first to fourth sub-pixels SP1 to SP4 are defined. In addition, a first color filter CF1, a second color filter CF2 and a third color filter CF3 may be formed such that they overlap emission areas EA1, EA2, and EA3 of the first, second and third sub-pixels SP1, SP2 and SP3, instead of the reflection adjustment layer RJ. For example, a first color filter CF1 may be formed to emit red light in wavelength ranges of approximately 600 nm to 750 nm, a second color filter CF2 may be formed to emit green light in wavelength ranges of approximately 495 nm to 570 nm, and a third color filter CF3 may be formed to emit blue light in wavelength ranges of approximately 450 nm to 495 nm.

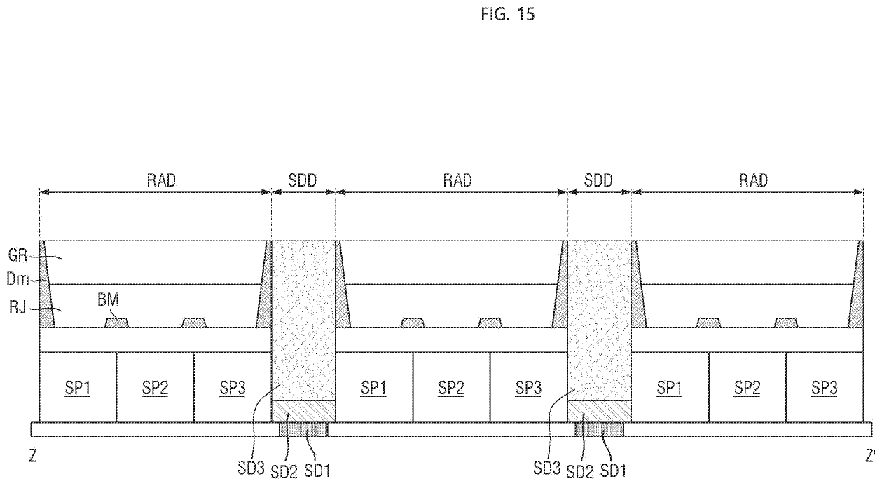

FIG. 15 is a cross-sectional view schematically showing an example of the display panel taken along the line Z-Z′ of FIG. 5 in the form of blocks.

Referring to FIGS. 4 and 15, unit pixels PX respectively formed in the rigid areas RAD are electrically and physically connected to other adjacent unit pixels PX by elastic connection members formed in a stretchable area SDD between the rigid areas RAD.

The elastic connection members include stretchable lines SD2 connected to the stretchable area SDD between the rigid areas RAD to transmit an electrical signal to each unit pixel PX, first elastic members SD1 physically attached between the rear surface of the stretchable lines SD2 and the rigid areas RAD and stretched by an external force while contracted by an elastic force, and second elastic members SD3 that are physically attached between the front surface of the stretchable lines SD2 and the rigid areas RAD, and stretched by an external force while contracted by an elastic force.

The stretchable lines SD2 may be made of a conductive material having an elongation ratio by itself or may be formed to have a spring-shaped curves, so that they can be stretched by an external force and can be contracted by the elastic force or by restoring force of the first and second elastic members SD1 and SD3. The stretchable lines SD2 may be gate lines, data lines, voltage lines, common lines, etc. sequentially connected to the sub-pixels SP1 to SP4.

The first and second elastic members SD1 and SD3 may be formed of a synthetic material based on elastomers. For example, the first and second elastic members SD1 and SD3 may include materials such as silicone elastomers, tyrannic elastomers, polyurethane (PU) elastomers, and/or synthetic rubbers.

The first and second elastic members SD1 and SD3 may surround the stretchable lines SD2. The stretchable lines SD2 are attached to the rigid areas RAD adjacent thereto.

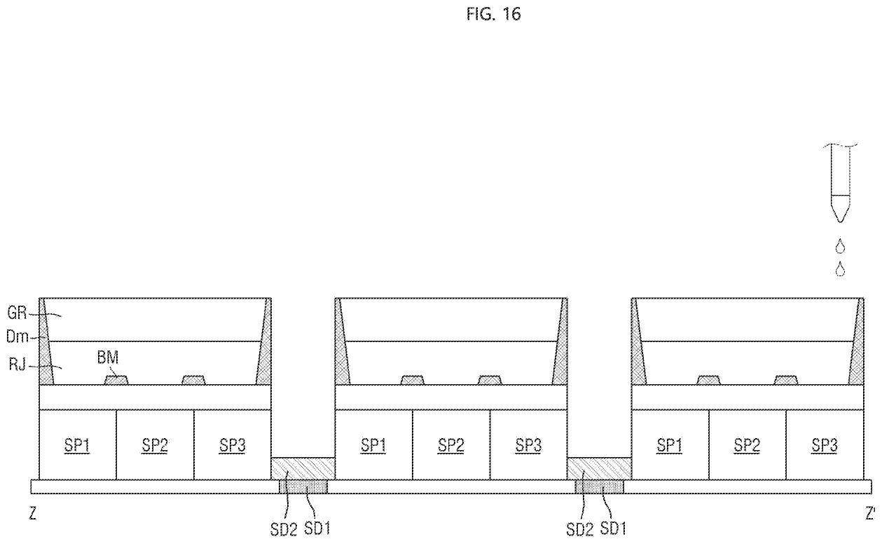

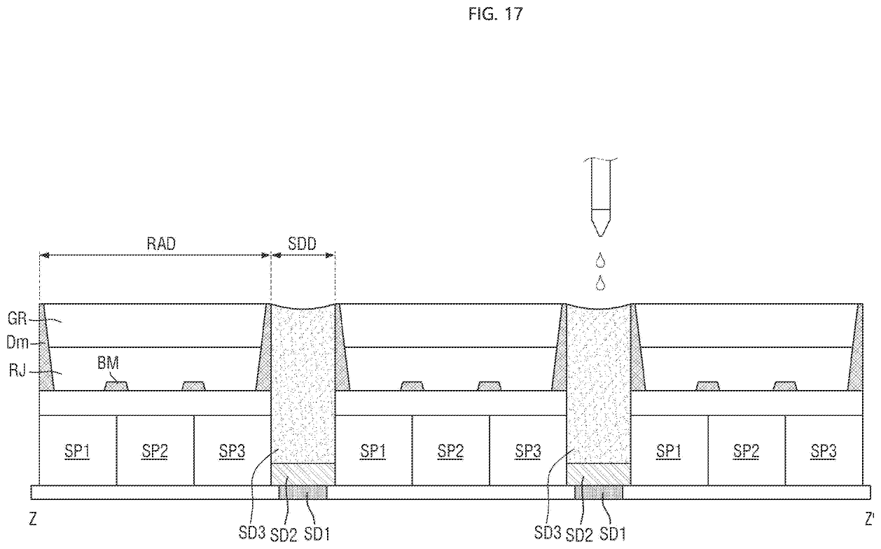

FIG. 16 is a cross-sectional view illustrating a method of fabricating the display panel shown in FIGS. 10 and 11. FIG. 17 is a cross-sectional view additionally illustrating the method of fabricating the display panel shown in FIGS. 10 and 11.

Referring to FIGS. 4, 16 and 17, a black matrix BM and a partition wall Dm are formed on the front surface (or upper surface) of each unit pixel PX. The partition wall Dm defines each unit pixel PX including first to fourth sub-pixels SP1 to SP4.

A reflection adjustment layer RJ including an organic layer in which dye and pigment are dispersed is applied and formed on the front surface of each unit pixel PX defined by the partition wall Dm to completely cover the black matrix BM. After the reflection adjustment layer RJ is applied, it may be cured via an additional curing process.

An optical adjustment layer GR that refracts and scatters light is additionally applied and formed on the front surface (or upper surface) of each unit pixel PX on which the reflection adjustment layer RJ is applied and formed so as to completely cover the reflection adjustment layer RJ. The optical adjustment layer GR stacked on the reflection adjustment layer RJ may be cured via an additional curing process.

In the area between the rigid areas RAD, i.e., in the stretchable area SDD, the second elastic members SD3 are applied so that they cover the first elastic members SD1 as well as the stretchable lines SD2 and are attached to the side surfaces of the rigid areas RAD adjacent thereto. The adhesive force and the elastic force of the second elastic members SD3 may be adjusted via an additional curing process.

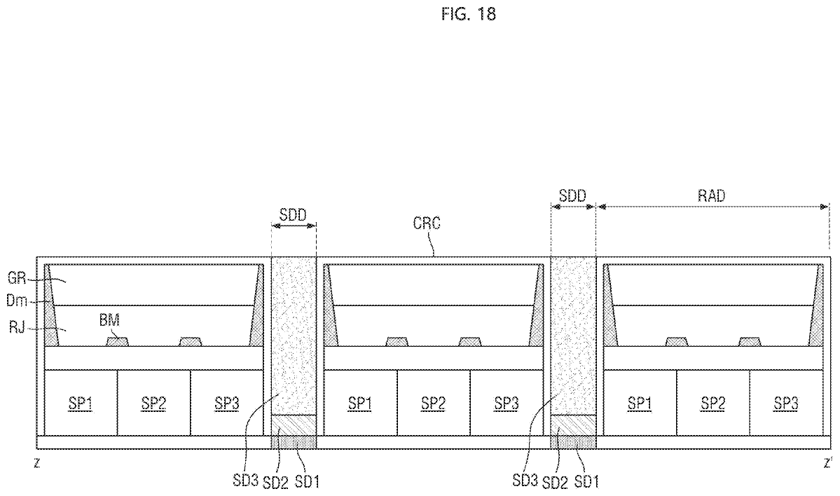

FIG. 18 is a cross-sectional view schematically showing another example of the configuration of the display panel, taken along the line Z-Z′ of FIG. 5.

Referring to FIG. 18, once the reflection adjustment layer RJ and the optical adjustment layer GR are sequentially stacked and cured on the front surface of each unit pixel PX defined by the partition wall Dm, an anti-moisture member CRC may be further formed to completely cover the rigid areas RAD including the partition wall Dm and the optical adjustment layer GR. In other words, each of the rigid areas RAD may further include the anti-moisture member CRC formed to cover all the outer surfaces of the rigid areas RAD, including the partition wall Dm and the optical adjustment layer GR. The anti-moisture member CRC covering the rigid areas RAD may be made up of a plurality of inorganic layers alternately stacked on one another. For example, the anti-moisture member CRC may be made up of multiple films in which one or more inorganic layers of a silicon nitride layer, a silicon oxynitride layer and a silicon oxide layer are alternately stacked on one another.

When the anti-moisture member CRC is formed to completely cover each of the rigid areas RAD, the second elastic members SD3 may be applied and formed in each stretchable area SDD so that they cover all the stretchable lines SD2 and are attached to the anti-moisture member CRC formed on the side surfaces of the rigid areas RAD.

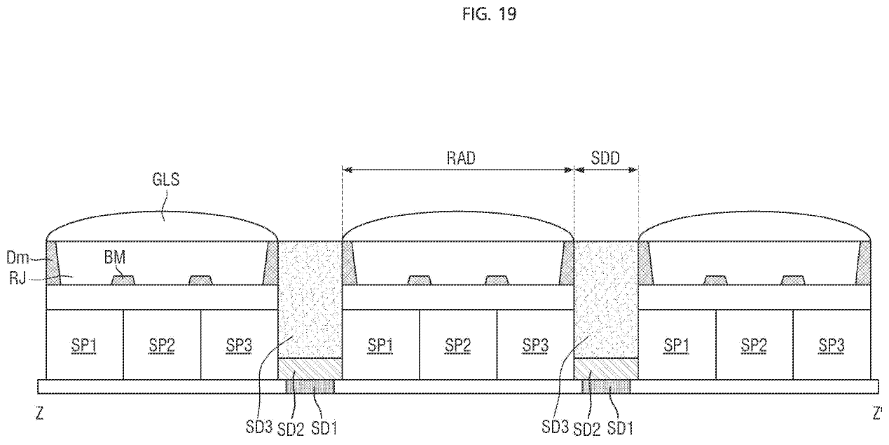

FIG. 19 is a cross-sectional view schematically showing yet another example of the configuration of the display panel, taken along the line Z-Z′ of FIG. 5.

Referring to FIG. 19, once the reflection adjustment layer RJ is stacked and cured on the front surface of each unit pixel PX defined by the partition wall Dm, refraction patterns GLS in the shape of a convex lens may be formed on the front surfaces of the partition wall Dm and the reflection adjustment layer RJ.

Each of the refraction patterns GLS may be formed on the front surface of the reflection adjustment layer RJ including the partition wall Dm (i.e., the front surface of each of the rigid areas RAD). Alternatively, when the optical adjustment layer GR is formed on the reflection adjustment layer RJ, each of the refraction patterns GLS may be formed on the front surface of the optical adjustment layer GR including the partition wall Dm. The refractive index of the refraction patterns GLS is greater than the refractive index of the reflection adjustment layer RJ or the optical adjustment layer GR, so that concentration degree of light and light output efficiency can be further improved.

In order to increase the concentration degree of light by each of the refraction patterns GLS, it is required to direct the light traveling in an oblique direction having an angle with the upward direction (or the front direction) so that the angle is reduced by the refraction patterns GLS. In order to direct the light traveling in the oblique direction, it is required to adjust a difference in refractive index between the refraction patterns GLS and the adjacent elements and the shape of each optical pattern. Furthermore, in order to concentrate light to the center of each of the sub-pixels SP1, SP2 and SP3 more reliably, it is required to adjust the refractive index of the refraction patterns GLS so that it is different from the refractive index of the reflection adjustment layer RJ or the optical adjustment layer GR, and it is also required to form the cross-sectional shape of the refraction patterns GLS into a convex lens typically used for concentrating light. Typically, a converging lens has the initial angle α of 30 degrees or more. Herein, the initial angle refers to the angle between the tangent line at the contact point where the lower surface of the refraction patterns GLS in contact with the upper surface of the reflection adjustment layer RJ and the convex surface of the refraction patterns GLS meet, and the lower surface of the refraction patterns GLS in contact with the upper surface of the reflection adjustment layer RJ in FIG. 19.

When the refraction patterns GLS are formed, the elastic members SD2 are formed such that they cover all of the stretchable lines SD2 of each stretchable area SDD except for the refraction pattern GLS and attached to the side surfaces of adjacent ones of the rigid areas RAD.

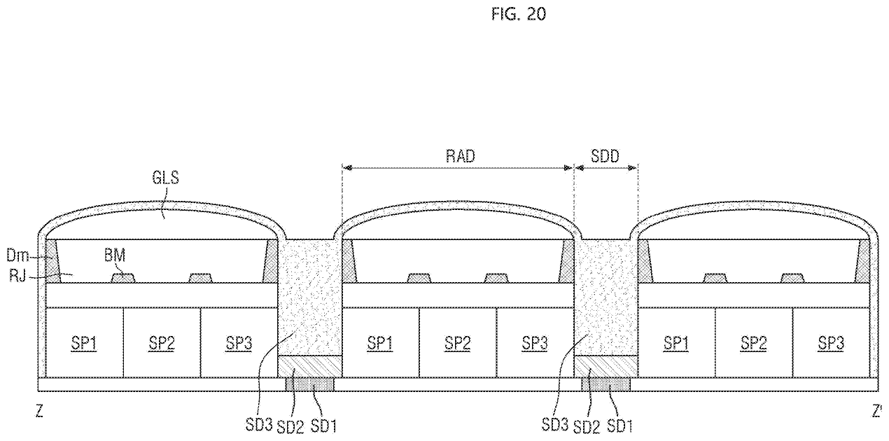

FIG. 20 is another cross-sectional view schematically showing the configuration of the display panel according to some embodiments, taken along the line Z-Z′ of FIG. 5.

As described above, the first and second elastic members SD1 and SD3 may be formed of a synthetic material based on elastomers. Such the first and second elastic members SD1 and SD3 may be formed of at least one material such as silicone elastomers, tyrannic elastomers, PU elastomers, and/or synthetic rubbers. Accordingly, the first and second elastic members SD1 and SD3 may be formed of a transparent material depending on the content of the composites.

Accordingly, the first and second elastic members SD1 and SD3 may be formed of a transparent synthetic material based on elastomers, and may cover all of the refraction patterns GLS and the stretchable lines SD2 while being attached to the side surfaces of adjacent ones of the unit pixels PX.

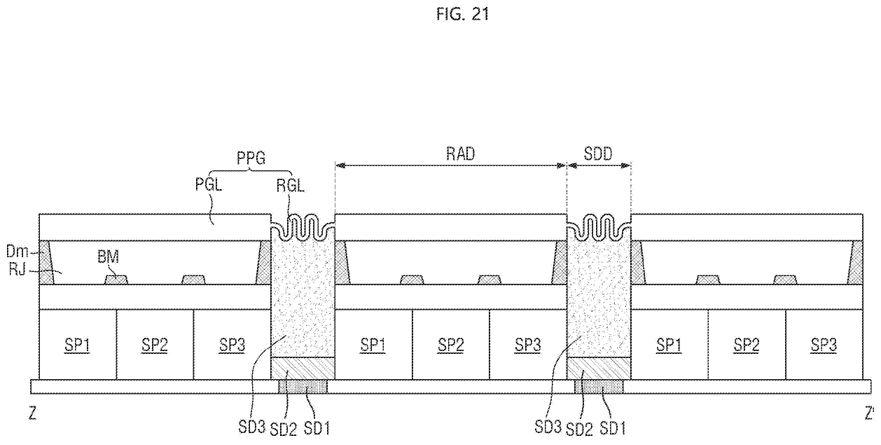

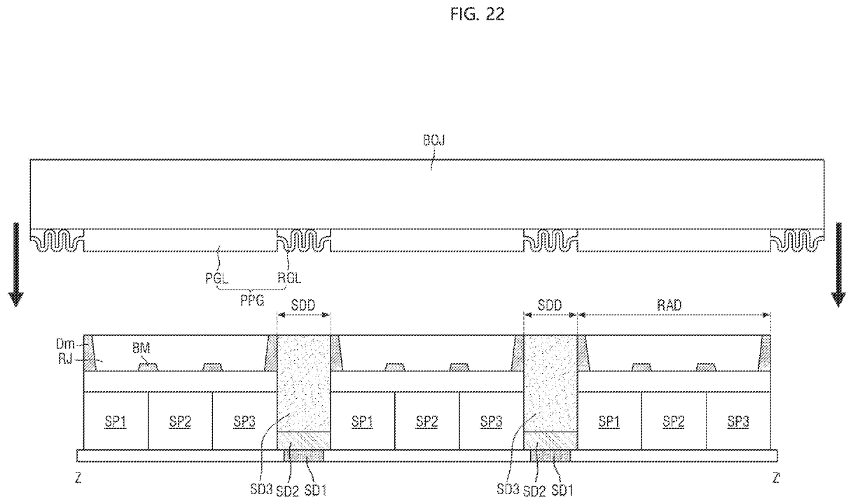

FIG. 21 is yet another cross-sectional view schematically showing the configuration of the display panel according to some embodiments, taken along the line Z-Z′ of FIG. 5. FIG. 22 is a cross-sectional view illustrating a method of fabricating the display panel shown in FIG. 21.

Referring to FIG. 21, when a reflection adjustment layer RJ is stacked on the front surface of each unit pixel PX defined by a partition wall Dm, second elastic members SD3 may be applied in a stretchable area SDD between rigid areas RAD so that they completely cover stretchable lines SD2 and are attached to the rigid areas RAD adjacent thereto. In addition, a flat protective plate, i.e., a window plate PPG may be formed on the front surface of the display area DA including the rigid areas RAD as well as the stretchable area SDD.

The window plate PPG includes a flat portion PGL located on the front portion of each of the rigid areas RAD, and a deformable portion RGL located on the front portion of the stretchable area SDD. The deformable portion RGL may include elements that can change the shape, such as a plurality of folding portions, folding surfaces, cutouts and holes, so that the length or width thereof may be changed when an external force is applied. The refractive index of the flat portion PGL may be different from the refractive index of the reflection adjustment layer RJ, for example, may be smaller than the refractive index of the reflection adjustment layer RJ. As shown in FIG. 22, the window plate PPG may be mounted on the front surface of the display area DA by a separate moving apparatus BOJ.

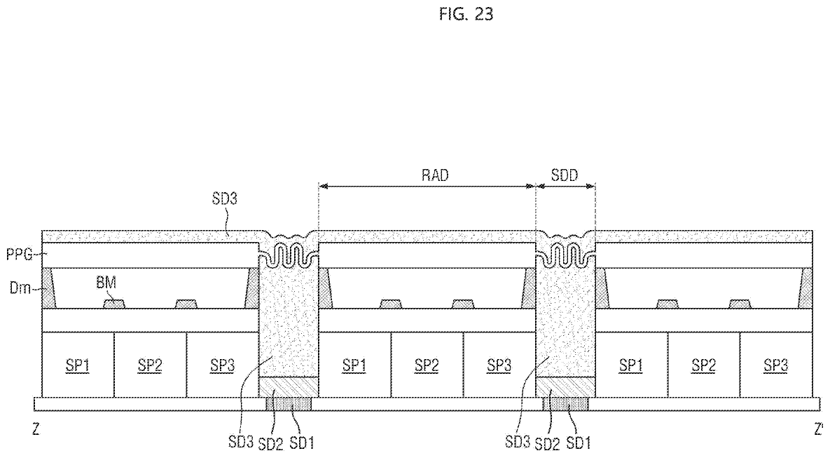

FIG. 23 is a cross-sectional view schematically showing a configuration of the display panel shown in FIG. 21 according to some embodiments.

As described above, the first and second elastic members SD1 and SD3 may include materials such as silicone elastomers, tyrannic elastomers, PU elastomers and synthetic rubbers, and thus they may be made of a transparent material depending on the contents of the composites.

Accordingly, as shown in FIG. 23, the second elastic members SD3 may be formed of a transparent synthetic material based on elastomers, and may cover all of the window plate PPG and the stretchable lines SD2 while being attached to the side surfaces of adjacent ones of the unit pixels PX.

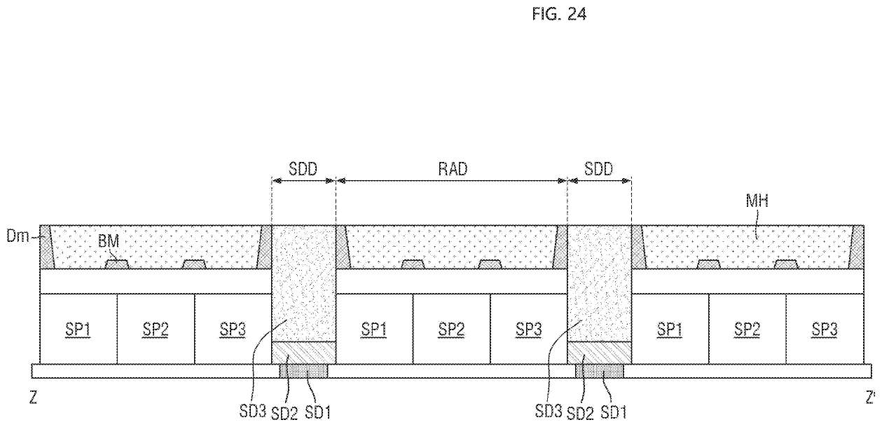

FIG. 24 is a cross-sectional view schematically showing another example of the configuration of the display panel, taken along the line Z-Z′ of FIG. 5.

Referring to FIG. 24, a mixed optical layer MH in which a reflection adjusting material and an optical adjusting material are mixed may be applied and formed on the front surface of each unit pixel PX defined by a partition wall Dm so that it completely covers a black matrix BM.

The mixed optical layer MAY HAVE may include an organic layer in which a dye and a pigment are dispersed to absorb light in particular wavelength ranges, and may further include at least one of an epoxy resin, an acrylic resin, a cardo resin, or an imide resin so that it is mixed therein. In addition, the mixed optical layer MH may include metal oxide particles or organic particles. The metal oxide may include titanium oxide, zirconium oxide, aluminum oxide, indium oxide, zinc oxide, or tin oxide. The organic particles may include an acrylic resin or a urethane resin.

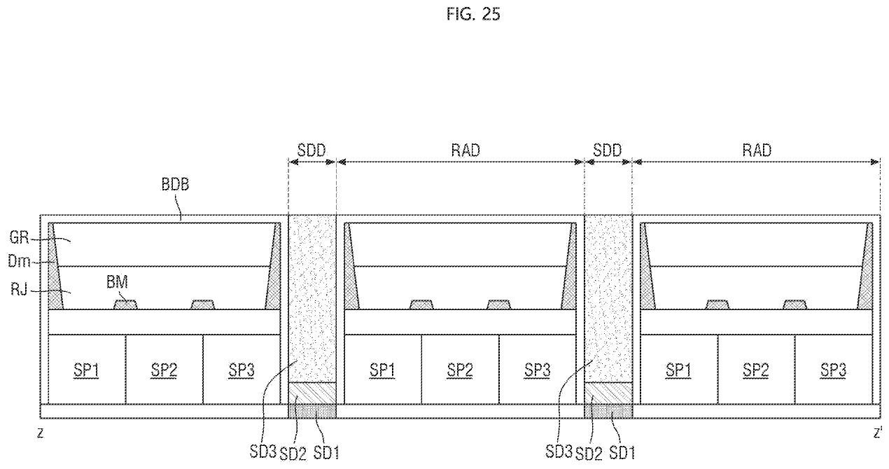

FIG. 25 is yet another cross-sectional view schematically an example of the configuration of the display panel, taken along the line Z-Z′ of FIG. 4 according to some embodiments.

Referring to FIG. 25, once the reflection adjustment layer RJ and the optical adjustment layer GR are sequentially stacked and cured on the front surface of each of the unit pixels PX defined by the partition wall Dm, an adhesive member BDB may be formed to cover the rigid areas RAD including the partition wall Dm and the optical adjustment layer GR. In other words, each of the rigid areas RAD may further include the adhesive member BDB formed to cover the entire outer surface. The adhesive member BDB which can enhance adhesion with the second elastic members SD3 may be formed of a plurality of organic layers alternately stacked on one another. The adhesive member BDB may be formed of multiple films in which at least one organic layer among a siloxane resin layer, an epoxy resin layer, an acryl resin layer, a phenolic resin layer, a polyamide resin layer, and a polyimide resin layer is alternately stacked on one another.

In the area between the rigid areas RAD, i.e., in the stretchable area SDD, the second elastic members SD3 may be formed so that they cover the stretchable lines SD2 and are attached to the adhesive member BDB of each of the rigid areas RAD.

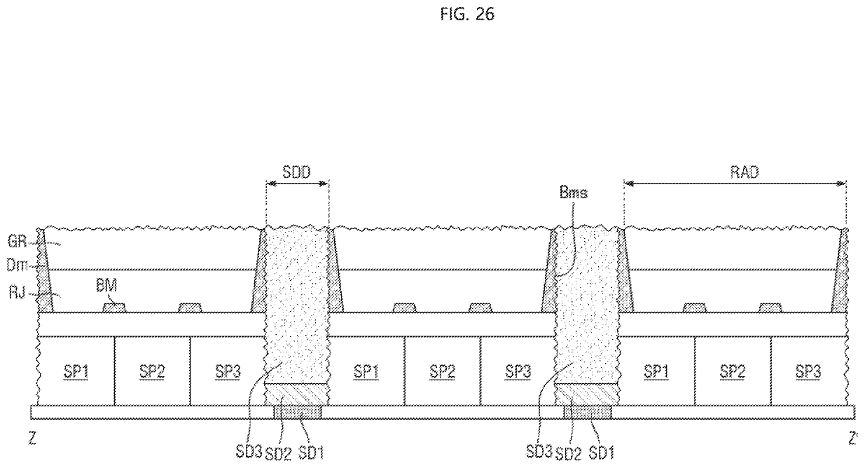

FIG. 26 is a cross-sectional view showing another method of fabricating the display panel shown in FIG. 15.

Referring to FIG. 26, once the reflection adjustment layer RJ and the optical adjustment layer GR are sequentially stacked and cured on the front surface of each unit pixel PX defined by the partition wall Dm, a technique for increasing the surface adhesion of each of the rigid areas RAD including the partition wall Dm and the optical adjustment layer GR may be carried out. For example, a plasma technique or the like may be carried out on each of the rigid areas RAD including the partition wall Dm and the optical adjustment layer GR, so that an irregular pattern Bms may be formed on the surface of each of the rigid areas RAD. In the area between the rigid areas RAD, i.e., in the stretchable area SDD, the second elastic members SD3 may be applied and formed so that they cover the stretchable lines SD2 and are attached to the irregular pattern Bms of each of the rigid areas RAD. Adhesion between the rigid areas RAD and the second elastic members SD3 can be enhanced by the surface including the irregular pattern.

FIG. 27 is a layout view showing a display area when it is contracted as a display panel is contracted according to some embodiments. FIG. 28 is a layout view showing a display area when it is stretched as the display panel is stretched according to some embodiments.

Referring to FIGS. 27 and 28, a plurality of unit pixels PX each including respective one of sub-pixels SP1, SP2 and SP3 is located in a display area DA of a display panel 100 to display images. The sub-pixels SP1, SP2 and SP3 may emit red, blue and green lights, respectively, to display images.

The display panel 100 includes the rigid areas RAD formed of the sub-pixels SP1 to SP3, respectively. For example, in the display panel 100, the sub-pixels SP1, SP2 and SP3 may be arranged in a Pentile™ matrix as they are partitioned by a partition wall, and the area where each of the sub-pixels SP1, SP2 and SP3 is located may be defined as a rigid area RAD.

Elastic connection members are formed in the area between the rigid areas RAD so that the distance pd between the rigid areas RAD each including the respective one of the sub-pixels SP1, SP2 and SP3 can be decreased or increased. The area in which the elastic connection members are formed is defined as a stretchable area SDD.

Each of the rigid areas RAD arranged in vertical or horizontal stripes or in a Pentile™ matrix is electrically connected to another adjacent rigid area RAD by the elastic connection members. In addition, the distance pd between the rigid areas RAD may be increased or decreased as the elastic connection members are stretched or contracted.

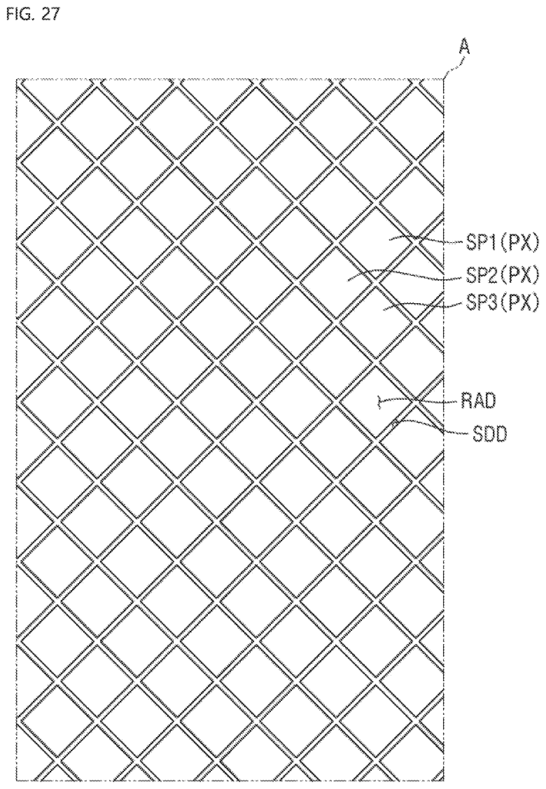

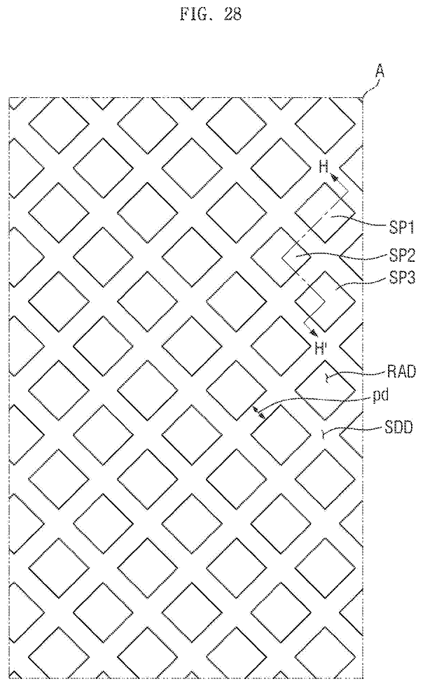

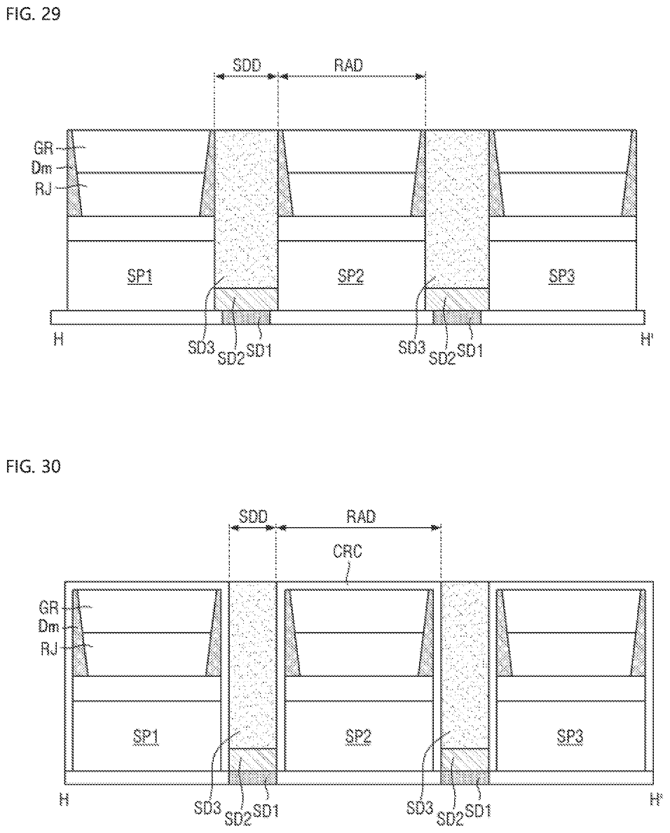

FIG. 29 is a cross-sectional view schematically showing an example of the display panel taken along the line H-H′ of FIG. 28 in the form of blocks.

Referring to FIG. 29, a black matrix BM and a partition wall Dm are formed on the front surface (or upper surface) of each of sub-pixels SP1, SP2 and SP3. The partition wall Dm defines each of rigid areas RAD.

A reflection adjustment layer RJ including an organic layer in which dye and pigment are dispersed is formed on the front surface of each of the rigid areas RAD defined by the partition wall Dm to completely cover the black matrix BM. After the reflection adjustment layer RJ is applied, it may be cured via an additional curing process.

An optical adjustment layer GR that refracts and scatters light is additionally formed on the front surface (or upper surface) of each of the rigid areas RAD on which the reflection adjustment layer RJ is applied and formed so as to completely cover the reflection adjustment layer RJ. The optical adjusting layer GR stacked on the reflection adjusting layer RJ may be cured via an additional curing process.

In the area between the rigid areas RAD, i.e., in the stretchable area SDD, the elastic members SD3 are applied so that they cover stretchable lines SD2 and are attached to the side surfaces of adjacent ones of the rigid areas RAD.

FIG. 30 is a cross-sectional view schematically showing another example of the configuration of the display panel, taken along the line H-H′ of FIG. 28.

Referring to FIG. 30, once the reflection adjustment layer RJ and the optical adjustment layer GR are sequentially stacked and cured on the front surface of each of the sub-pixels SP1, SP2 and SP3 partitioned by the partition wall Dm, i.e., on the front surface of each of the rigid areas RAD, an anti-moisture member CRC may be formed to cover each of the rigid areas RAD including the partition wall Dm and the optical adjustment layer GR. In other words, each of the rigid regions RAD may further include the anti-moisture member CRC formed to cover all the outer surfaces of the rigid regions RAD, including the partition wall Dm and the optical adjustment layer GR. The anti-moisture member CRC of the rigid areas RAD may be made up of a plurality of inorganic layers alternately stacked on one another. Accordingly, in the area between the rigid areas RAD, i.e., in the stretchable area SDD, the second elastic members SD3 may be applied and formed so that they cover all of the stretchable lines SD2 and are attached to the anti-moisture member CRC of the side surfaces of each of the rigid areas RAD.

In addition to the embodiments in which the anti-moisture member CRC is formed on the front surface of each of the rigid areas RAD, the configurations of the rigid areas RAD according to the embodiments shown in FIGS. 19, 20 and 23 to 26 may be equally applied to the sub-pixels SP1, SP2 and SP3. Some of them will be described in more detail below.

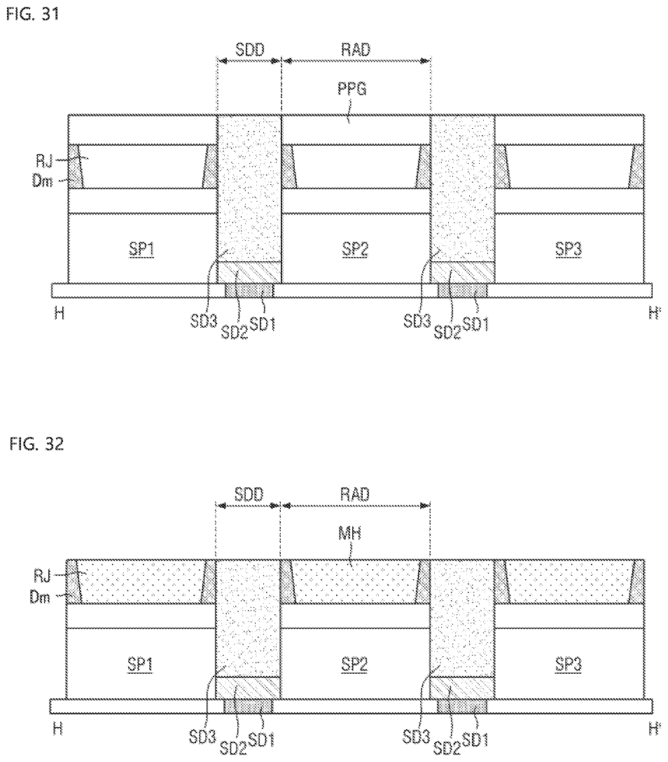

FIG. 31 is a cross-sectional view schematically showing yet another example of the configuration of the display panel, taken along the line H-H′ of FIG. 28.

Referring to FIG. 31, when a reflection adjustment layer RJ is stacked on the front surface of each of the rigid areas RAD defined by a partition wall Dm, second elastic members SD2 may be applied in a stretchable area SDD between the rigid areas RAD so that they cover all of the stretchable lines SD2 and are attached to the adjacent rigid areas RAD. Accordingly, in each of the rigid areas RAD including the partition wall Dm and the reflection adjustment layer RJ, a flat window plate PPG may be formed for each of the rigid areas RAD.

Each window plate PPG may be located on the front portion of the respective rigid area RAD, and the refractive index of the window plate PPG may be different from, for example, smaller than, the refractive index of the reflection adjustment layer RJ.

FIG. 32 is another cross-sectional view schematically showing an example of the configuration of the display panel, taken along the line H-H′ of FIG. 28.

Referring to FIG. 32, a mixed optical layer MH in which a reflection adjusting material and an optical adjusting material are mixed may be applied and formed on the front surface of each of the rigid areas RAD defined by a partition wall Dm so that it completely covers a black matrix BM.

The mixed optical layer MAY HAVE may include an organic layer in which a dye and a pigment are dispersed to absorb light in particular wavelength ranges, and may further include at least one of an epoxy resin, an acrylic resin, a cardo resin, or an imide resin so that it is mixed therein.

The mixed optical layer MH may include metal oxide particles or organic particles. The metal oxide may include titanium oxide (TiO₂), zirconium oxide (ZrO₂), aluminum oxide (Al₂O₃), indium oxide (In₂O₃), zinc oxide (ZnO), or tin oxide (SnO₂). The organic particles may include an acrylic resin or a urethane resin.

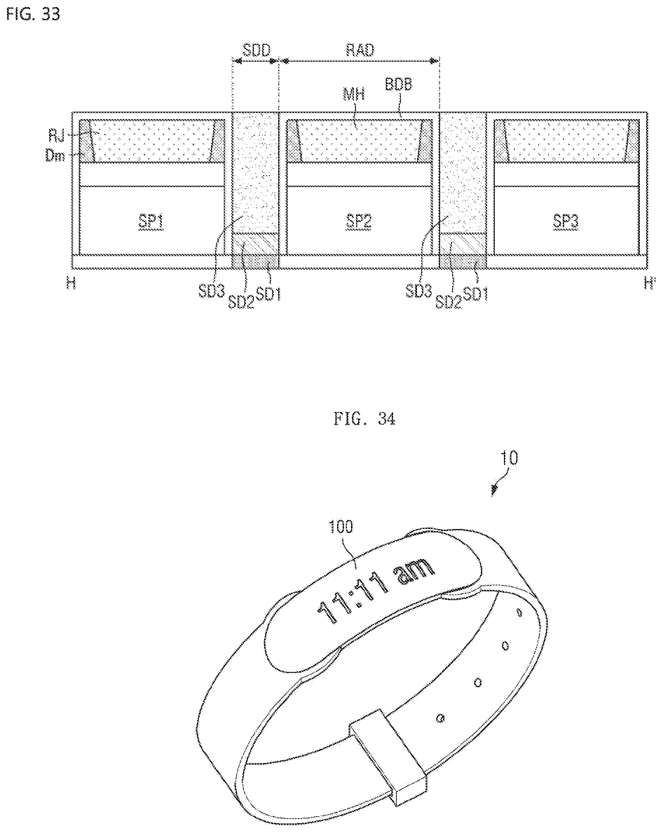

FIG. 33 is a cross-sectional view schematically showing yet another example of the configuration of the display panel, taken along the line H-H′ of FIG. 28.

Referring to FIG. 33, a mixed optical layer MH in which a reflection adjusting material and an optical adjusting material are mixed may be formed and cured on the front surface of each rigid area RAD partitioned by the partition wall Dm. In addition, when the mixed optical layer MH is cured, an adhesive member BDB may be formed to cover each of the rigid areas RAD including the partition wall Dm and the mixed optical layer MH. In other words, each of the rigid areas RAD may further include the adhesive member BDB formed to cover the entire outer surface of the rigid areas RAD. The adhesive member BDB may include a plurality of organic layers alternately stacked on one another. The adhesive member BDB may be formed of multiple films in which at least one organic layer among a siloxane resin layer, an epoxy resin layer, an acryl resin layer, a phenolic resin layer, a polyamide resin layer, and a polyimide resin layer is alternately stacked on one another.

Accordingly, in the area between the rigid areas RAD, the second elastic members SD3 may be applied and formed so that they cover all of the stretchable lines SD2 and are attached to the adhesive member BDB of each of the rigid areas RAD.

FIG. 34 is a view showing an example of a wearable device including a display device according to some embodiments of the present disclosure.

Referring to FIG. 34, a display device 10 according to some embodiments may be a device wearable on a user's body or a patch-type wearable device. The wearable display device 10 according to some embodiments may be deformed such that a display area DA is widened or narrowed as a display panel 100 is contracted or stretched.

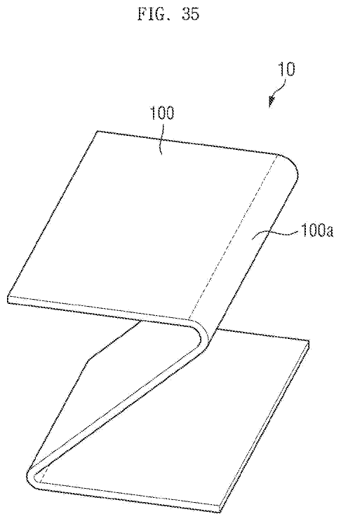

FIG. 35 is a view showing an example of a foldable smart device including a display device according to some embodiments of the present disclosure.

Referring to FIG. 35, a display device 10 according to some embodiments may be a foldable mobile communications device. The foldable display device 10 according to some embodiments may be deformed such that a display area DA is widened or narrowed as a display panel 100 is contracted or stretched. The display panel 10 according to some embodiments of the present disclosure may be applied on a deformable area 100a of the display area DA where images are displayed, which can deform as it is folded and unfolded, so that the display panel 10 can be contracted or stretched.

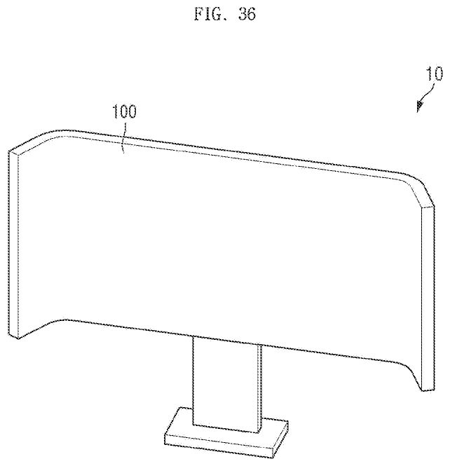

FIG. 36 is a view showing an example of a large monitor including a display device according to some embodiments.

Referring to FIG. 36, a display device 10 according to some embodiments may be a large monitor applicable to large TVs, electric billboards, monitors, laptop computers, etc. The display device 10 for a large monitor according to some embodiments may be deformed such that a part of a display area DA is widened or narrowed as a display panel 100 is deformed.

As described above, according to some embodiments of the present disclosure, the quality of images of the display device 10 can be maintained without deterioration even when the display panel 100 for displaying images is stretched or contracted, so that user satisfaction and display quality can be improved.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a display area; and
a non-display area on at least one side of the display area,
wherein the display area comprises:
a plurality of rigid areas, in each of which at least one unit pixel comprising a plurality of sub-pixels is defined by a partition wall; and
a stretchable area in which elastic connection members are formed between the plurality of rigid areas to enable a distance between the plurality of rigid areas to be increased or decreased.

2. The display device of claim 1, wherein the at least one unit pixel in each of the plurality of rigid areas comprises first to third sub-pixels or first to fourth sub-pixels, and
wherein the first to third sub-pixels or the first to fourth sub-pixels are arranged in vertical or horizontal stripes or a Pentile™ matrix.

3. The display device of claim 1, wherein the at least one unit pixel in each of the plurality of rigid areas comprises a reflection adjustment layer formed on a front surface to cover a black matrix, and
wherein the reflection adjustment layer comprises an organic layer in which a dye is dispersed and an organic layer in which a pigment is dispersed, such that the reflection adjustment layer is configured to absorb light in a predetermined wavelength range and transmit light in other wavelength ranges.

4. The display device of claim 3, wherein the elastic connection members comprise:
stretchable lines connected between the plurality of rigid areas to transmit an electrical signal to the at least one unit pixel;
first elastic members between rear surfaces of the stretchable lines and the plurality of rigid areas, and configured to be stretched by an external force and contracted by an elastic force; and
second elastic members between front surfaces of the stretchable lines and the plurality of rigid areas, and configured to be stretched by an external force and contracted by an elastic force.

5. The display device of claim 4, wherein each of the plurality of rigid areas comprises an optical adjustment layer on a front surface of the reflection adjustment layer defined by the partition wall to refract and scatter light after the light has transmitted the reflection adjustment layer.

6. The display device of claim 5, wherein each of the plurality of rigid areas further comprises an anti-moisture member formed to completely cover an outer surface thereof, comprising the partition wall and the optical adjustment layer, and wherein the second elastic members cover all of the stretchable lines and are attached to the anti-moisture member of the plurality of rigid areas.

7. The display device of claim 5, wherein each of the plurality of rigid areas further comprises an adhesive member formed to completely cover an outer surface thereof, comprising the partition wall and the optical adjustment layer, and wherein the elastic members cover all of the stretchable lines and are attached to the adhesive member of the plurality of rigid areas.

8. The display device of claim 4, wherein the plurality of rigid areas further comprise refraction patterns formed on a front surface of the reflection adjustment layer defined by the partition wall to refract and scatter light after the light has transmitted the reflection adjustment layer, and
wherein the refraction patterns are formed in a shape of a convex lens such that a refractive index thereof is different from a refractive index of the reflection adjustment layer.

9. The display device of claim 8, wherein the second elastic members are formed of a transparent synthetic material based on elastomers, to cover all of the refraction patterns and the stretchable lines while being attached to side surfaces of adjacent ones of the plurality of rigid areas.

10. The display device of claim 4, wherein the plurality of rigid areas further comprise a flat window plate formed on a front surface comprising the partition wall and the reflection adjustment layer, and
wherein the window plate comprises a flat portion on a front portion of the plurality of rigid areas, and a deformable portion on a front portion of the stretchable area.

11. The display device of claim 10, wherein the second elastic members are formed of a transparent synthetic material based on elastomers, to cover all of the window plate and the stretchable lines while being attached to side surfaces of adjacent ones of the plurality of rigid areas.

12. A display device comprising:
a display area; and
a non-display area on at least one side of the display area,
wherein the display area comprises:
a plurality of rigid areas, in each of which a respective one of sub-pixels is defined by a partition wall; and
a stretchable area in which elastic connection members are formed between the plurality of rigid areas to enable a distance between the plurality of rigid areas to be decreased or increased.

13. The display device of claim 12, wherein each of the sub-pixels in the respective plurality of rigid areas comprises a reflection adjustment layer formed on a front surface to cover a black matrix, and
wherein the reflection adjustment layer comprises an organic layer in which a dye is dispersed and an organic layer in which a pigment is dispersed, such that the reflection adjustment layer is configured to absorb light in a predetermined wavelength range and to transmit light in other wavelength ranges.

14. The display device of claim 13, wherein the elastic connection members comprise:
stretchable lines connected between the plurality of rigid areas to transmit an electrical signal between the sub-pixels;
first elastic members physically attached between rear surfaces of the stretchable lines and the plurality of rigid areas, and configured to be stretched by an external force and contracted by an elastic force; and
second elastic members physically attached between front surfaces of the stretchable lines and the plurality of rigid areas, and configured to be stretched by an external force and contracted by an elastic force.

15. The display device of claim 14, wherein each of the plurality of rigid areas further comprises an optical adjustment layer formed on a front surface of the reflection adjustment layer defined by the partition wall to refract and scatter light after the light has transmitted the reflection adjustment layer.

16. The display device of claim 15, wherein each of the plurality of rigid areas further comprises an anti-moisture member formed to completely cover an outer surface thereof, comprising the partition wall and the optical adjustment layer, and wherein the elastic members cover all of the stretchable lines and are attached to the anti-moisture member of the sub-pixels.

17. The display device of claim 15, wherein each of the plurality of rigid areas further comprises an adhesive member formed to completely cover an outer surface thereof, comprising the partition wall and the optical adjustment layer, and wherein the elastic members cover all of the stretchable lines and are attached to the adhesive member of the plurality of rigid areas.

18. The display device of claim 14, wherein the plurality of rigid areas further comprise refraction patterns formed on a front surface of the reflection adjustment layer defined by the partition wall to refract and scatter light after the light has transmitted the reflection adjustment layer, and
wherein the refraction patterns are formed in a shape of a convex lens so that a refractive index thereof is greater than a refractive index of the reflection adjustment layer.

19. The display device of claim 18, wherein the second elastic members are formed of a transparent synthetic material based on elastomers, to cover all of the refraction patterns and the stretchable lines while being attached to side surfaces of adjacent ones of the plurality of rigid areas.

20. The display device of claim 14, wherein each of the plurality of rigid areas further comprises a flat window plate on a front surface of the partition wall and the reflection adjustment layer, and
wherein a refractive index of the window plate is different from that of the reflection adjustment layer.
